(19) United States
(12) Patent Application Publication
(10) Pub. No.: US 2026/0198159 A1
(43) Pub. Date: Jul. 9, 2026

(54) DISPLAY DEVICE INCLUDING REFLECTIVE FILM COVERING ORGANIC PARTITION WALL, MANUFACTURING METHOD OF THE SAME AND ELECTRONIC DEVICE

(71) Applicant: SAMSUNG DISPLAY CO., LTD., YONGIN-SI (KR)

(72) Inventors: Tae Sang PARK, Yongin-si (KR); Yun Jong YEO, Yongin-si (KR); Ki Chang EOM, Yongin-si (KR); Hyun Min CHO, Yongin-si (KR)

(21) Appl. No.: 19/292,606

(22) Filed: Aug. 6, 2025

(30) Foreign Application Priority Data
Jan. 9, 2025 (KR) 10-2025-0003151

(51) Int. Cl. H10H 29/80; H01L 25/075; H10H 29/01; H10H 29/41

(52) U.S. Cl. CPC H10H 29/8421; H10H 29/012; H10H 29/41; H10W 90/00

(57) ABSTRACT

A display device includes a thin film transistor layer, a first via layer, a second via layer having a via layer opening, a pixel electrode layer, a light-emitting element, an organic partition wall, a reflective film covering the organic partition wall and including a protrusion portion extending along a side surface of the second via layer exposed by the via layer opening and a top surface of the first via layer and protruding toward the light-emitting element, and a first insulating film disposed on a bottom surface of the reflective film. The protrusion portion overlaps an edge of the pixel electrode layer in a thickness direction, and the pixel electrode layer and the reflective film are spaced apart from each other.

### CROSS-REFERENCE TO RELATED APPLICATION

The present application claims priority under 35 U.S.C. 119 to and the benefit of Korean Patent Application No. 10-2025-0003151, filed on Jan. 9, 2025, in the Korean Intellectual Property Office, the entire disclosure of which is herein incorporated by reference.

### TECHNICAL FIELD

The present disclosure relates to a display device and, more specifically, to a display device including a reflective film covering an organic partition wall, a manufacturing method of the same, and an electronic device.

### DISCUSSION OF THE RELATED ART

As technology advances, the demand for various types of image display devices continues to grow. These display devices include flat panel display devices such as liquid crystal displays, field emission displays, light-emitting displays, and the like.

Among the light-emitting displays, there are two main types: organic light-emitting display devices, which use organic light-emitting diodes (OLEDs), ultra-small light emitting display devices that use micro light-emitting diode elements (hereinafter referred to as a micro light emitting elements). Since micro light-emitting diode elements include an inorganic material, it has the advantage of having a long lifespan, due to less deterioration, compared to organic light-emitting diode elements.

### SUMMARY

A display device includes a substrate, a thin film transistor layer disposed on the substrate, a first via layer disposed on the thin film transistor layer, a second via layer disposed on the first via layer and having a via layer opening, a pixel electrode layer disposed within the via layer opening on the first via layer, a light-emitting element disposed on the pixel electrode layer, an organic partition wall disposed on the second via layer, a reflective film covering the organic partition wall and including a protrusion portion extending along a side surface of the second via layer exposed by the via layer opening and a top surface of the first via layer and protruding toward the light-emitting element and a first insulating film disposed on a bottom surface of the reflective film. The protrusion portion overlaps an edge of the pixel electrode layer in a thickness direction. The pixel electrode layer and the reflective film are spaced apart from each other.

The protrusion portion may be lower than the lower end of the light-emitting element.

The display device may further include a second insulating film disposed on a top surface of the reflective film and surrounding top surface and side surfaces of the protrusion portion.

The pixel electrode layer may include a pixel electrode and a protective film surrounding side surfaces of the pixel electrode.

The protrusion portion may overlap the protective film in a thickness direction.

The protrusion portion may overlap an edge of the pixel electrode in a thickness direction and may be spaced apart from the pixel electrode.

The first insulating film and the pixel electrode disposed on the bottom surface of the protrusion portion may be spaced apart from each other.

The pixel electrode layer may include a pixel electrode and a protective film surrounding side surfaces of the pixel electrode.

The display device may further include a bonding electrode disposed between the light-emitting element and the pixel electrode and extending between a bottom surface of the first insulating film and a top surface of the pixel electrode.

The organic partition wall may include a single-layer or multi-layer organic layer.

The organic partition wall may have an inclination angle formed between a first outer surface facing the first light-emitting element and an imaginary surface extending parallel to a contact surface of the light-emitting element and a bonding electrode.

The inclination angle may be within a range of 120 to 135 degrees, inclusive.

The light-emitting element may further include a protective film disposed on side surfaces of the first semiconductor layer, the active layer, and the second semiconductor layer, wherein the light-emitting element does not have a reflective film disposed on the side surfaces of the first semiconductor layer, the active layer, and the second semiconductor layer on the protective film.

The display device may further include a common electrode disposed on a top surface of the light-emitting element. The light-emitting element may be disposed on the pixel electrode.

The pixel electrode layer may further include a common electrode. The pixel electrode and the common electrode may be spaced apart from each other. The protective film may surround a side surface of the pixel electrode and a side surface of the common electrode. The light-emitting element may be disposed on the pixel electrode and the common electrode.

The light-emitting element may include a first contact electrode disposed on the pixel electrode and a second contact electrode disposed on the common electrode.

A method for manufacturing a display device includes forming a pixel electrode and a protective film covering the pixel electrode on a first via layer of a substrate, covering the protective film with a via material layer on the first via layer, forming an organic partition wall on the via material layer, forming a second via layer having a first opening exposing the protective film by ashing a portion of the via material layer, forming a first insulating layer and a reflective film covering the organic partition wall and exposing the protective film in the first opening, forming an insulating material layer surrounding the reflective film, first etching the insulating material layer in the first opening to form a second insulating layer, and then second etching the protective film to expose the pixel electrode and the bonding a light-emitting element on the pixel electrode after the first etching has been performed. The reflective film has a protrusion portion extending along a top surface of the first via layer and protruding toward the light-emitting element and overlapping an edge of the pixel electrode layer in a thickness direction.

The first etching may be a dry etching and the second etching may be a wet etching, and an etchant of the first etching may be a material that etches the insulating material layer but does not etch the protective film.

A bonding electrode may be disposed between the light-emitting element and the pixel electrode and the light-emitting element may be bonded to the pixel electrode by hot pressing.

An electronic device includes a display panel, a window disposed on the display panel, and a bottom cover disposed below the display panel. The display panel includes a substrate, a thin film transistor layer disposed on the substrate, a first via layer disposed on the thin film transistor layer, a second via layer disposed on the first via layer and having a via layer opening, a pixel electrode layer disposed within the via layer opening on the first via layer, a light-emitting element disposed on the pixel electrode layer, an organic partition wall disposed on the second via layer, a reflective film covering the organic partition wall and including a protrusion portion extending along a side surface of the second via layer exposed by the via layer opening and a top surface of the first via layer and protruding toward the light-emitting element and a first insulating film disposed on a bottom surface of the reflective film. The protrusion portion overlaps an edge of the pixel electrode layer in a thickness direction, and the pixel electrode layer and the reflective film are spaced apart from each other.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a perspective view illustrating a display device according to an embodiment.

FIG. 2 is a layout drawing illustrating a display device according to an embodiment.

FIG. 3 is a block drawing illustrating a display device according to an embodiment.

FIG. 4 is an equivalent circuit drawing illustrating a sub-pixel according to an embodiment.

FIG. 5 is a layout drawing illustrating pixels of a display FIG. 5 is a layout drawing illustrating pixels of a display area according to an embodiment.

FIG. 6 is a cross-sectional view illustrating an example of a cross-section of a display panel corresponding to line I-I′ in FIG. 5.

FIG. 7 is a cross-sectional view illustrating an example of area A1 of FIG. 6 in detail.

FIG. 8 is a cross-sectional view illustrating the arrangement structure of the protrusion area of FIG. 7.

FIG. 9 is a cross-sectional view illustrating the arrangement structure of the protrusion area of FIG. 7 according to an embodiment.

FIG. 10 is a plan view illustrating the reflective film, pixel electrode, and light-emitting element of FIG. 7.

FIG. 11 is a cross-sectional view illustrating an example of the A area of FIG. 6 in detail.

FIG. 12 is a layout diagram illustrating pixels of a display area according to an embodiment.

FIG. 13 is a cross-sectional view illustrating an example of a cross-section of a display panel corresponding to line I2-I2′ in FIG. 11.

FIG. 14 is a cross-sectional view illustrating an example of the B area of FIG. 13 in detail.

FIG. 15 is a cross-sectional view illustrating an example of area B of FIG. 14 in detail.

FIG. 16 is a flow chart illustrating a method for manufacturing a display device according to an embodiment.

FIGS. 17 to 26 are exemplary drawings to illustrate a method for manufacturing a display device according to an embodiment.

FIGS. 27 and 28 are exemplary drawings illustrating a smart watch including a display device according to an embodiment.

FIG. 29 is an exploded perspective view of a smart watch including a display device according to an embodiment.

FIG. 30 is an example views of a virtual reality (VR) device including a display device according to one or more embodiments.

FIG. 31 is an example view of a VR device including a display device according to one or more embodiments.

FIG. 32 is an example view illustrating a vehicle instrument cluster and center fascia including display devices according to one or more embodiments.

FIG. 33 is an example view of a transparent display device including a display device according to one or more embodiments.

### DETAILED DESCRIPTION

Aspects and features of the present disclosure, and the methods for achieving them, will become clear with reference to the embodiments described in detail below with the accompanying drawings. However, the present disclosure is not necessarily limited to the embodiments disclosed below, but may be implemented in many different forms, and these embodiments are provided to make the disclosure of the present disclosure complete and to fully inform those skilled in the art of the disclosure of the scope of the disclosure.

References to an element or layer as being “on” another element or layer include both cases where the other layer or element is directly on top of or interposed between other elements. The same reference numerals may refer to the same components throughout the specification and the drawings. The shapes, sizes, ratios, angles, numbers, etc. disclosed in the drawings to illustrate the embodiments are exemplary, and therefore the present disclosure is not necessarily limited to the matters illustrated.

Each feature of the various embodiments of the present disclosure may be partially or entirely combined or combined with each other and may be technically capable of various interconnections and operations. Each embodiment may be implemented independently of each other or may be implemented together in a related relationship. Specific embodiments are described below with reference to the attached drawings.

Embodiments of the present disclosure relate to a novel structure and manufacturing method for a micro light-emitting diode (micro-LED) display device. An architecture is used that increases frontal light-emitting efficiency through the integration of a unique reflective and insulating layer configuration around the light-emitting element. This display device includes a substrate with a thin film transistor layer, followed by stacked via layers that house a pixel electrode and a light-emitting element. An organic partition wall is constructed around the light-emitting region, and a reflective film is applied in a specific geometry that overlaps the pixel electrode's edge while maintaining separation from it. This layout, particularly the 120 to 135-degree average inclination angle of the organic partition wall, allows better directionality of emitted light toward the front, enhancing brightness and efficiency.

The pixel electrode sits inside an opening in the via layers and is electrically connected to transistors below. On top of and around this assembly, the reflective film extends along the exposed side surfaces of the via layers and protrudes toward the light-emitting element. This reflective structure effectively recycles light that would otherwise be wasted by redirecting it forward. To ensure electrical insulation and mechanical stability, multiple insulating films surround and support the reflective film. The entire structure is optimized to minimize light absorption and leakage, thus increasing the light output and operational efficiency of the display.

Protective films and bonding electrodes are used to facilitate secure attachment of the micro-LED elements to the pixel electrodes. These layers also help in maintaining the structural integrity during the transfer and alignment process of the light-emitting elements. The reflective film's protrusion, combined with the organic partition wall, plays a role in shaping the optical path, preventing lateral dispersion of light, and contributing to a uniform and bright display appearance. Moreover, the device optionally includes color filters and capping layers to ensure precise color rendering and encapsulation.

The manufacturing method also reflects these goals by employing a combination of dry and wet etching techniques, hot pressing for bonding, and multi-step deposition of organic and inorganic layers. The fabrication sequence emphasizes precise patterning and layering to produce the desired structure with high alignment accuracy. This approach can be applied in a range of electronic devices, including smartwatches, VR headsets, vehicle displays, and other consumer electronics requiring high-performance display panels with excellent light output and durability. The structure not only increases efficiency but is also compatible with flexible and transparent display formats, offering wide applicability.

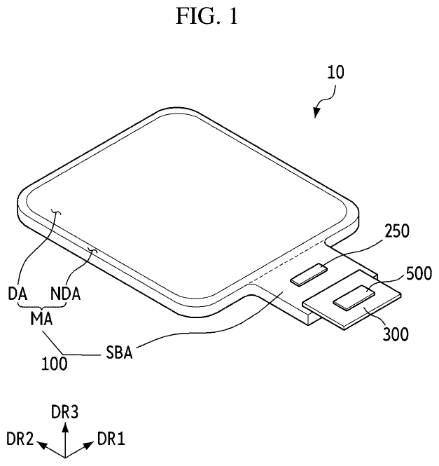

FIG. 1 is a perspective view illustrating a display device according to an embodiment.

Referring to FIG. 1, a display device 10 is a device for displaying video or still images, such as may be used in mobile phones, smart phones, tablet computers, and portable electronic devices such as smart watches, watch phones, mobile communication terminals, electronic notebooks, e-books, portable electronic devices such as portable multimedia players (PMP), navigation systems, and ultra mobile PC (UMPC), as well as display screens for a variety of products such as televisions, laptop/notebook computers, computer monitors, digital billboards, and the internet of things (IOT) devices.

The display device 10 may be a light-emitting display device, such as an organic light-emitting display device utilizing an organic light-emitting diode (OLED), a quantum dot light-emitting display device including a quantum dot light-emitting layer, an inorganic light-emitting display device including an inorganic semiconductor, and a miniaturized light-emitting display device utilizing a micro or nano light-emitting diode (micro LED or nano LED). Hereinafter, the description focuses on the fact that the display device 10 is a micro-light emitting display device, but the present disclosure is not necessarily limited thereto. On the other hand, hereinafter, an ultra-small light-emitting diode is described as a light-emitting element for convenience of explanation.

The display device 10 includes a display panel 100, a display driving circuit 250, a circuit substrate 300, and a power supply circuit 500.

The display panel 100 may have a rectangular shaped plane having a pair of short side each extending primarily in the first direction DR1 and a pair of long side each extending primarily in the second direction DR2 that intersects the first direction DR1. A corner where the short side in the first direction DR1 and the long side in the second direction DR2 meet may be rounded to have a predetermined curvature or may be formed at a right angle. The planar shape of the display panel 100 is not necessarily limited to a rectangle, but may be formed in other polygonal, circular, or oval shapes. The display panel 100 may be formed flat but is not necessarily limited thereto. In an example, the display panel 100 may be formed at the left and right ends and may include curved portions with a constant curvature or a changing curvature. In addition, the display panel 100 may be flexibly formed to be bent, curved, bent, folded, or rolled to at least an appreciable degree without cracking or otherwise sustaining damage.

The display panel 100 may include the main area MA and the sub-area SBA.

The main area MA may include a display area DA that displays an image and a non-display area NDA that is a surrounding area of the display area DA. The display area DA may include a plurality of pixels that display an image. Each pixel may include a plurality of sub-pixels. For example, each of the pixels may include a first sub-pixel that emits a first light, a second sub-pixel that emits a second light, and a third sub-pixel that emits a third light, but the embodiments of the present disclosure are not necessarily limited thereto.

The sub-area SBA may protrude from one side of the main area MA in the second direction DR2. Although FIG. 1 illustrates the sub-area SBA being unfolded, the sub-area SBA may be bent, and in this case, may be disposed on the lower surface of the display panel 100. When the sub-area SBA is bent, it may overlap the main area MA in a third direction DR3, which is the thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached to the indication panel 100 using a chip on glass (COG) method, a chip on plastic (COP) method, or an ultrasonic bonding method but is not necessarily limited thereto. In an embodiment, the display driving circuit 250 may be attached to the circuit substrate 300 using a chip on film (COF) method.

The circuit substrate 300 may be attached to one end of the sub-area SBA of the display panel 100. As such, the circuit substrate 300 may be electrically connected to the display panel 100 and the display driving circuit 250. The display panel 100 and the display driving circuit 250 may receive digital video data, timing signals, and driving voltages through the circuit substrate 300. The circuit substrate 300 may be a flexible film, such as a flexible printed circuit substrate, a printed circuit substrate, or a chip on film.

The power supply circuit 500 may generate a plurality of panel driving voltages according to an external power supply voltage. The power supply circuit 500 may be formed as an integrated circuit (IC) and attached to the circuit substrate 300 using a COF method.

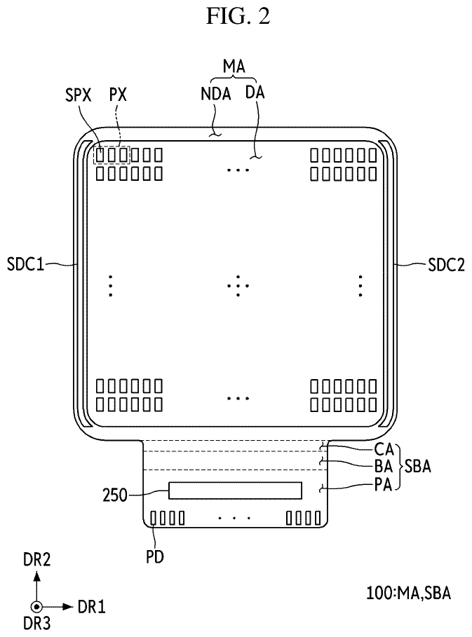

FIG. 2 is a layout drawing illustrating a display device according to an embodiment. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA that is a peripheral area of the display area DA. The display area DA may occupy most of the area of the main area MA. The display area DA may be placed in the center of the main area MA.

The display area DA includes a plurality of pixels PX for displaying an image, and each of the plurality of pixels PX may include a plurality of sub-pixels SPX. A pixel PX may be defined as a sub-pixel group of the smallest unit capable of expressing a white grayscale.

The non-display area NDA may be disposed adjacent to the display area DA. The non-display area NDA may be an area outside of the display area DA. The non-display area NDA may surround the display area DA. The non-display area NDA may be an edge area of the display panel 100.

A first scan driving portion SDC1 and a second scan driving portion SDC2 may be disposed in the non-display area NDA. The first scan driving portion SDC1 is disposed on one side (e.g., the left side) of the display panel 100, and the second scan driving portion SDC2 is disposed on the other side (e.g., the right side) of the display panel 100 but are not necessarily limited thereto. Each of the first scan driving portion SDC1 and the second scan driving portion SDC2 may be electrically connected to the display driving circuit 250 through scan fan out lines. Each of the first scan driving portion SDC1 and the second scan driving portion SDC2 may receive a scan control signal from the display driving circuit 250, generate scan signals according to the scan control signal, and output them to scan lines.

The sub-area SBA may protrude from one side of the main area MA in the second direction DR2. The length of the sub-area SBA in the second direction DR2 may be smaller than the length of the main area MA in the second direction DR2. The length of the first direction DR1 of the sub area SBA may be less than the length of the first direction DR1 of the main area MA or may be substantially equal to the length of the first direction DR1 of the main area MA. The sub-area SBA may be curved and may be disposed at a lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driving circuit 250 are disposed. The display driving circuit 250 may be attached to the driving pads of the pad area PA using a conductive adhesive such as an anisotropic conductive film. The circuit substrate 300 may be attached to the pads PD of the pad area PA using a conductive adhesive such as an anisotropic conductive film. One side of the pad area PA may be in contact with the bending area BA.

The bending area BA is a bent area. When the bending area BA is bent, the pad area PA may be disposed below the connection area CA and below the main area MA. The bending area BA may be disposed between the connection area CA and the pad area PA. One side of the bending area BA may be in contact with the connection area CA, and the other side of the bending area BA may be in contact with the pad area PA.

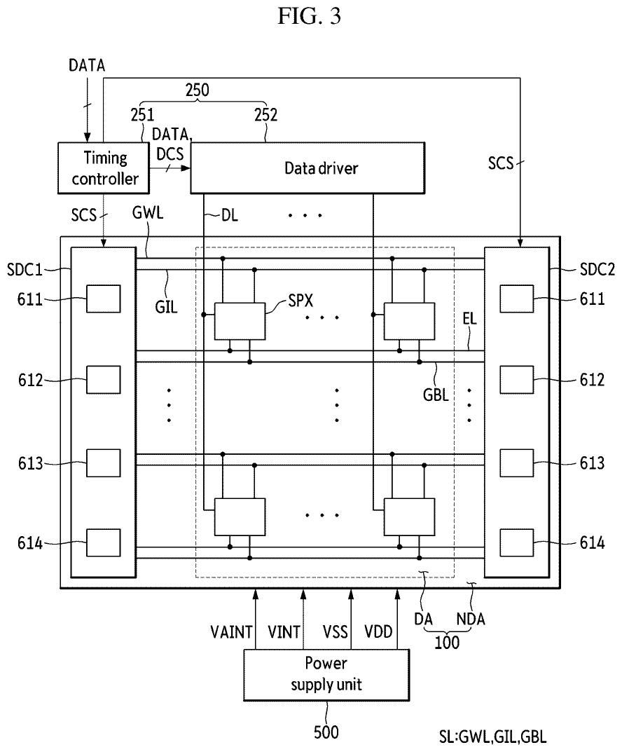

FIG. 3 is a block drawing illustrating a display device according to an embodiment.

Referring to FIG. 3, the display area DA includes a plurality of pixels PX, a plurality of scan lines SL, a plurality of emission control lines EL, and a plurality of data lines DL.

The plurality of pixels PX may be in a matrix form in the first direction DR1 and the second direction DR2. The plurality of scan lines SL and the plurality of emission control lines EL may extend in the first direction DR1 and be disposed in the second direction DR2. The plurality of data lines DL may extend in the second direction DR2 and be disposed in the first direction DR1. The plurality of scan lines SL may include a plurality of write scan lines GWL, a plurality of control scan lines GCL, a plurality of initialization scan lines GIL, and a plurality of bias scan lines GBL.

Each of the plurality of sub-pixels SPX may be connected to a write scan line GWL from among the plurality of write scan lines GWL, a control scan line GCL from among the plurality of control scan lines GCL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. Each of the plurality of sub-pixels SPX may be supplied with a data voltage of the data line DL according to the write scan signal of the write scan line GWL and may emit light-emitting elements according to the data voltage.

The non-display area NDA includes a first scan driving portion SDC1, a second scan driving unit SDC2, and a display driving circuit 250.

Each of the first scan driving portion SDC1 and the second scan driving portion SDC2 may include a write scan signal output portion 611, an initialization scan signal output portion 612, a bias scan signal output portion 613, and an emission control signal output portion 614. Each of the write scan signal output portion 611, the initialization scan signal output portion 612, the bias scan signal output portion 613, and the emission control signal output portion 614 may receive a scan timing control signal SCS from a timing control circuit 251.

The write scan signal output portion 611 may generate write scan signals according to the scan timing control signal SCS of the timing control circuit 251 and sequentially output them to the write scan lines GWL.

The initialization scan signal output portion 612 may generate initialization scan signals according to the scan timing control signal SCS and sequentially output them to the initialization scan lines GIL.

The bias scan signal output portion 613 may generate bias scan signals according to the scan timing control signal SCS and sequentially output them to the bias scan lines GBL. The emission control signal output portion 614 may generate emission control signals according to the scan timing control signal SCS and sequentially output them to the emission control lines EL.

The display driving circuit 250 includes a timing control circuit 251 and a data driving circuit 252.

The data driving circuit 252 may receive digital video data DATA and a data timing control signal DCS from the timing control circuit 251. The data driving circuit 252 converts digital video data DATA into analog data voltages according to the data timing control signal DCS and outputs them to the data lines DL. In this case, the sub-pixels SPX are selected by the write scan signals of the first scan driving unit SDC1 and the second scan driving unit SDC2, and data voltages may be supplied to the selected sub-pixels SPX.

The timing control circuit 251 may receive digital video data DATA and timing signals from an external source. The timing control circuit 251 may generate a scan timing control signal SCS and a data timing control signal DCS for controlling the display panel 100 according to the timing signals. The timing control circuit 400 may output the scan timing control signal SCS to the first scan driving portion SDC1 and the second scan driving portion SDC2. The timing control circuit 251 may output digital video data DATA and a data timing control signal DCS to the data driving circuit 252.

The power supply circuit 500 may generate a plurality of panel driving voltages according to a power voltage supplied from an external source. For example, the power supply circuit 500 may generate a first power supply voltage VDD, a second power supply voltage VSS, a third power supply voltage VINT, and a fourth power supply voltage VAINT and supply them to the display panel 100.

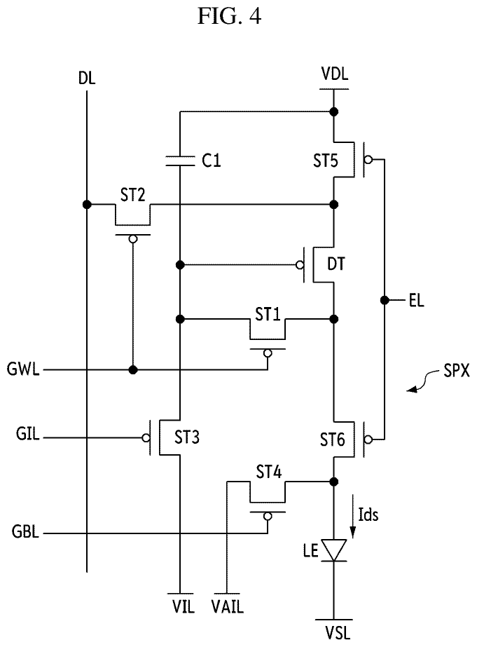

FIG. 4 is an equivalent circuit drawing illustrating a sub-pixel according to an embodiment.

Referring to FIG. 4, a sub-pixel SPX, according to an embodiment, may be connected to scan lines GWL, GIL, and GBL, an emission control line EL, and a data line DL. For example, the sub-pixel SPX may be connected to a write scan line GWL, an initialization scan line GIL, a bias scan line GBL, an emission control line EL, and a data line DL.

The sub-pixel SPX, according to an embodiment, includes a driving transistor DT, switching elements, a capacitor C1, and a lighting element LE. The switching elements include first to sixth transistors ST1, ST2, ST3, ST4, ST5, and ST6.

The driving transistor DT includes a gate electrode, a first electrode, and a second electrode. The driving transistor DT controls a drain-source current (“Ids”, hereinafter referred to as “driving current”) flowing between the first electrode and the second electrode according to a data voltage applied to a gate electrode.

The light-emitting element LE1 may be a micro light-emitting diode.

The light-emitting element LE emits light according to the driving current Ids. The amount of light emitted from the light-emitting element LE may be proportional to the driving current Ids. The anode electrode of the light-emitting element LE is connected to the first electrode of the fourth transistor ST4 and the second electrode of the sixth transistor ST6, and the cathode electrode may be connected to a second power supply line VSL to which a second power supply voltage is applied.

A capacitor C1 is formed between a gate electrode of a driving transistor DT and a first power supply line VDL to which a first power supply voltage is applied. The first power supply voltage may be a voltage of a higher level than the second power supply voltage. One electrode of the capacitor C1 may be connected to the gate electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as p-type MOSFET. In this case, the active layer of each of the first to sixth transistors ST1, ST2, ST3, ST4, ST5, and ST6 and the driving transistor DT may be formed of polysilicon.

The gate electrode of the first transistor ST1 and the gate electrode of the second transistor ST2 may be connected to the write scan line GWL, and the gate electrode of the third transistor ST3 may be connected to the initialization scan line GIL, and the gate electrode of the fourth transistor ST4 may be connected to the bias scan line GBL. Since the first to sixth transistors ST1, ST2, ST3, ST4, ST5, and ST6 are formed as p-type MOSFET and they may be turned on when a scan signal of a gate low voltage and an emission control signal are applied to the initialization scan line GIL, the write scan line GWL, the bias scan line GBL, and the emission line EL, respectively. One electrode of the third transistor ST3 may be connected to the first initialization voltage line VIL to which the third power supply voltage (VINT of FIG. 3) is applied, and one electrode of the fourth transistor ST4 may be connected to the second initialization voltage line VAIL to which the fourth power supply voltage (VAINT of FIG. 3) is applied. The third power supply voltage (VINT of FIG. 3) and the fourth power supply voltage (VAINT of FIG. 3) may be different voltages. Further, the third power supply voltage (VINT in FIG. 3) and the fourth power supply voltage (VAINT in FIG. 3) may be voltages at a lower level than the first power supply voltage VDD and at a higher level than the second power supply voltage VSS.

Alternatively, the driving transistor DT, the second transistor ST2, the fourth transistor ST4, the fifth transistor ST5, and the sixth transistor ST6 may be formed of a p-type MOSFET, and the first transistor ST1 and the third transistor ST3 may be formed of an n-type MOSFET. In this case, the active layers of each of the driving transistor DT, the second transistor ST2, the fourth transistor ST4, the fifth transistor ST5, and the sixth transistor ST6 formed of p-type MOSFETs are formed of polysilicon, the active layers of each of the first transistor ST1 and the third transistor ST3 formed of an n-type MOSFET may be formed of an oxide semiconductor. Furthermore, since the first transistor ST1 and the third transistor ST3 are formed as n-type MOSFET, the first transistor ST1 may be turned on when a scan signal of the gate high voltage is applied, and the third transistor ST3 may be turned on when an initialization scan signal of the gate high voltage is applied. In contrast, the second transistor ST2, the fourth transistor ST4, the fifth transistor ST5, and the sixth transistor ST6 are formed as p-type MOSFET, so they may be turned on when a scan signal of the gate low voltage and a light emission control signal are applied.

Alternatively, the fourth transistor ST4 may be formed as an n-type MOSFET, and the remaining transistors DT, ST1, ST2, ST3, ST5, and ST6 may be formed as p-type MOSFET, in which case the active layer of the fourth transistor ST4 may be formed as an oxide semiconductor, and the active layers of each of the remaining transistors DT, ST1, ST2, ST3, ST5, and ST6 may be formed as polysilicon. Further, the fourth transistor ST4 may be turned on when a scan signal of a gate high voltage is applied, whereas the remaining transistors DT, ST1, ST2, ST3, ST5, and ST6 may be turned on when a scan signal of a gate low voltage and a light emission control signal are applied.

Alternatively, the first to sixth transistors ST1, ST2, ST3, ST4, ST5, and ST6 and the driving transistor DT may all be formed as n-type MOSFET. In this case, the active layer of each of the first to sixth transistors ST1, ST2, ST3, ST4, ST5, and ST6 and the driving transistor DT is formed of an oxide semiconductor and may be turned on when a scan signal of a gate high voltage and a light emission control signal are applied.

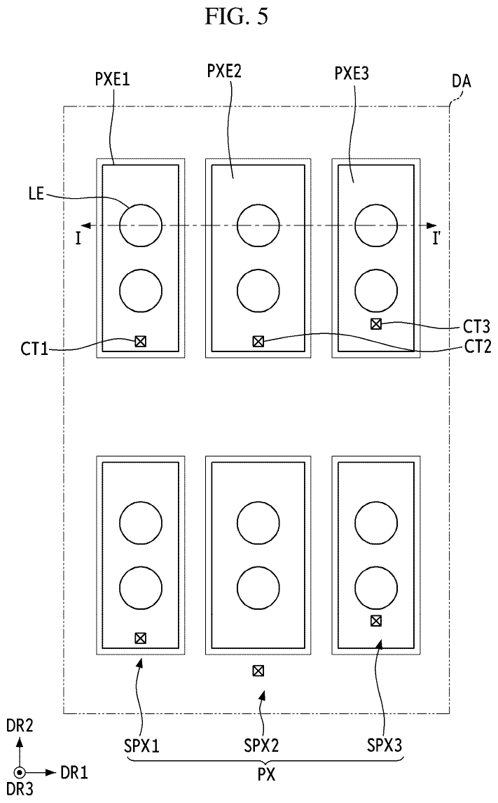

FIG. 5 is a layout drawing illustrating pixels of a display area according to an embodiment.

Referring to FIG. 5, each of the plurality of pixels PX of the display area DA may include three sub-pixels SPX1, SPX2, and SPX3, but the embodiment of the present disclosure is not necessarily limited thereto and may include four sub-pixels. When each of the plurality of pixels PX includes three sub-pixels SPX1, SPX2, and SPX3, the first sub-pixel SPX1, the second sub-pixel SPX2, and the third sub-pixel SPX3 may include.

The plurality of pixels PX may be in a matrix form. In each of the plurality of pixels PX, the first sub-pixel SPX1, the second sub-pixel SPX2, and the third sub-pixel SPX3 may be arranged in a first direction DR1.

When each of the plurality of pixels PX includes three sub-pixels SPX1, SPX2, and SPX3, the first sub-pixel SPX1 may emit light of a first color, and the second sub-pixel SPX2 may emit light of a second color, and the third sub-pixel SPX3 may emit light of a third color. The first color light may be light in a red wavelength band, the second color light may be light in a green wavelength band, and the third color light may be light in a blue wavelength band. For example, the blue wavelength band may refer to light having a main peak wavelength in the wavelength band from approximately 370 nm to 460 nm, the green wavelength band may refer to light having a main peak wavelength in the wavelength band from approximately 480 nm to 560 nm, and the red wavelength band may refer to light having a main peak wavelength in the wavelength band from approximately 600 nm to 750 nm.

Alternatively, when each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. In this case, the fourth color light may be white light.

The first sub-pixel SPX1 includes a first pixel electrode PXE1 and a plurality of light-emitting elements LE. The second sub-pixel SPX2 includes a second pixel electrode PXE2 and a plurality of light-emitting elements LE. The third sub-pixel SPX3 includes a third pixel electrode PXE3 and a plurality of light-emitting elements LE.

The light-emitting element LE1 of the first sub-pixel SPX1 may emit light of a first color, the light-emitting element LE2 of the second sub-pixel SPX2 may emit light of a second color, and the light-emitting element LE3 of the third sub-pixel SPX3 may emit light of a third color.

Each of the first pixel electrode PXE1, the second pixel electrode PXE2, and the third pixel electrode PXE3 may have a rectangular planar shape having a pair of short sides extending primarily in a first direction DR1 and a pair of long sides extending primarily in a second direction DR2. The area of the first sub-pixel SPX1, the area of the second sub-pixel SPX2, and the area of the third sub-pixel SPX3 may be set according to the light-emitting efficiency of the light-emitting element LE included in each sub-pixel SPX. For example, the area of the sub-pixel may be larger as the light conversion efficiency is lower.

For example, as shown in FIG. 5, when the light-emitting efficiency of the light-emitting element LE2 of the second sub-pixel SPX2 is lower than the light-emitting efficiency of the light-emitting element LE1 of the first sub-pixel SPX1 and the light-emitting element LE2 of the third sub-pixel SPX2, the area of the second pixel electrode PXE2 may be larger than the area of the first pixel electrode PXE1 and larger than the area of the third pixel electrode PXE2.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the second electrode of the fourth transistor (ST4 in FIG. 4) and the second electrode of the sixth transistor (ST6 in FIG. 4) of the corresponding sub-pixel.

A plurality of light-emitting elements LE may be disposed on each of the pixel electrodes PXE1, PXE2, and PXE3. The same number of light-emitting elements LE may be disposed on each of the pixel electrodes PXE1, PXE2, and PXE3. For example, two light-emitting elements LE may be disposed on each of the pixel electrodes PXE1, PXE2, and PXE3. The plurality of light-emitting elements LE may emit light of a third color, i.e., light in a blue wavelength band, but the embodiment of the present disclosure is not necessarily limited thereto.

Each of the plurality of light-emitting elements LE may have a circular planar shape, but the embodiment of the present disclosure is not necessarily limited thereto. For example, each of the plurality of light-emitting elements LE may have a rectangular planar shape.

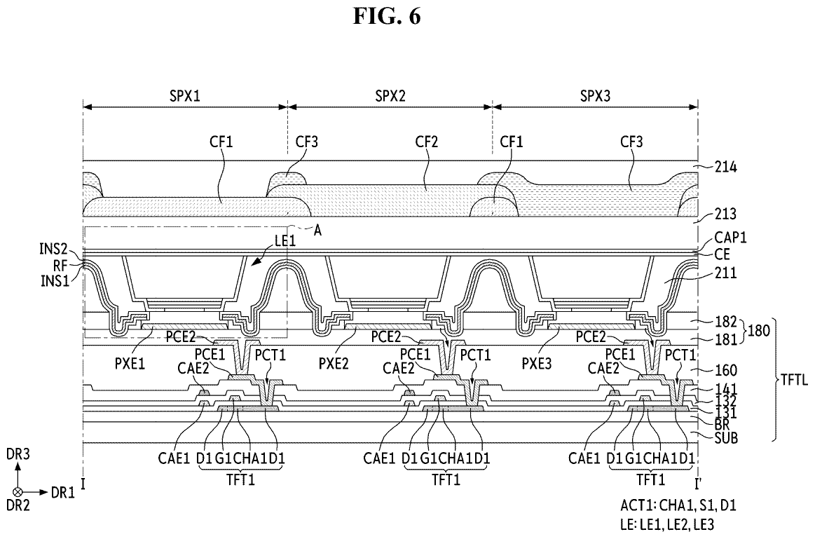

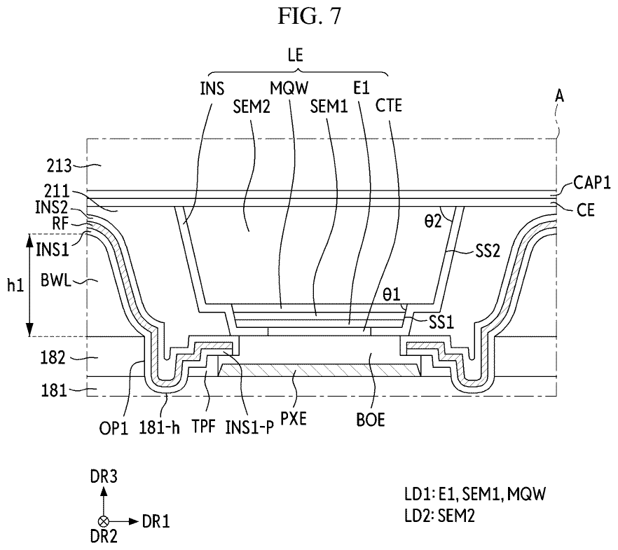

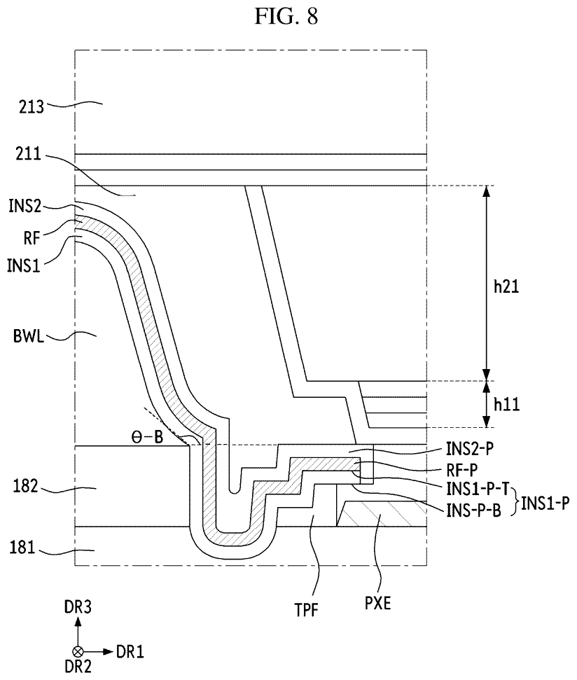

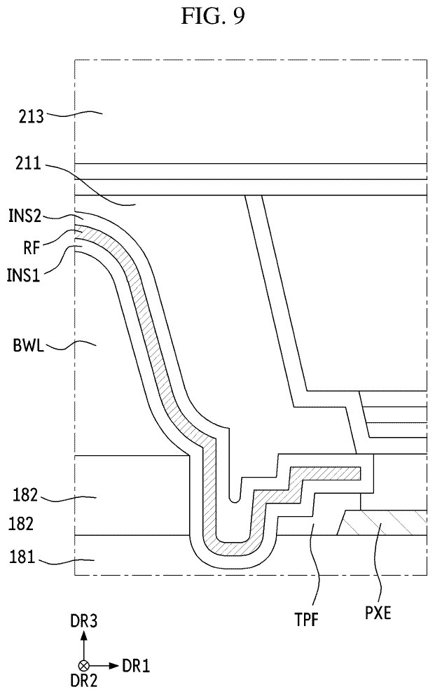

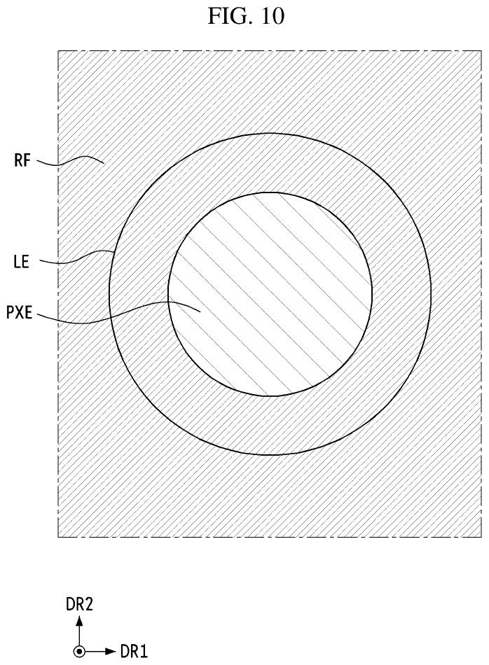

FIG. 6 is a cross-sectional view illustrating an example of a cross-section of a display panel corresponding to line I-I′ in FIG. 5. FIG. 7 is a cross-sectional view illustrating an example of area A1 of FIG. 6 in detail. FIG. 8 is a cross-sectional view illustrating the arrangement structure of the protrusion area of FIG. 7. FIG. 9 is a cross-sectional view illustrating the arrangement structure of the protrusion area of FIG. 7 according to an embodiment. FIG. 10 is a plan view illustrating the reflective film, pixel electrode, and light-emitting element of FIG. 7.

Referring to FIGS. 6 and 7, a substrate SUB may be made of an insulating material such as glass, polymer resin, or the like. If the substrate SUB is made of polymer resin, it may be a flexible substrate that may be stretched. The polymer resin may be acrylic resin, epoxy resin, phenolic resin, polyamide resin, polyimide resin, or the like.

A barrier film BR may be disposed on the substrate SUB. The barrier film BR is a film that protects a thin-film transistor layer TFTL from moisture penetrating through the substrate SUB which is vulnerable to moisture permeation. The barrier film BR may be formed of a plurality of inorganic films that are alternately stacked.

A thin film transistor TFT1 may be disposed on the barrier film BR. The thin film transistor TFT1 may be either the fourth transistor ST4 or the sixth transistor ST6 shown in FIG. 4. The thin film transistor TFT1 may include a first active layer ACT1 and a first gate electrode G1.

The first active layer ACT1 of the thin film transistor TFT1 may be disposed on the barrier film BR. The first active layer ACT1 of the thin film transistor TFT1 may include polycrystalline silicon, monocrystalline silicon, low-temperature polycrystalline silicon, or amorphous silicon. Alternatively, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be disposed on one side of the first channel area CHA1, and the first drain area D1 may be disposed on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be disposed on the first channel area CHA1, the first source area S1, and the first drain area D1 of the thin film transistor TFT1.

A first gate metal layer may be disposed on the first gate insulating film 131. The first gate metal layer may include a first gate electrode G1 of a thin film transistor TFT1 and a first capacitor electrode CAE1. The first gate electrode G1 may overlap the first active layer ACT1 in the third direction DR3. Although the first gate electrode G1 and the first capacitor electrode CAE1 are illustrated as being spaced apart from each other in FIG. 6, the first gate electrode G1 and the first capacitor electrode CAE1 may be connected to each other.

A second gate insulating film 132 may be disposed on the first gate electrode G1 and the first capacitor electrode CAE1 of the thin film transistor TFT1.

A second gate metal layer may be disposed on the second gate insulating film 132. The second gate metal layer may include a second capacitor electrode CAE2. The second capacitor electrode CAE2 may overlap the first capacitor electrode CAE1 of the thin film transistor TFT1 in the third direction DR3. Since the second gate insulating film 132 has a predetermined dielectric constant, the capacitor (C1 in FIG. 4) may be formed by the first capacitor electrode CAE1, the second capacitor electrode CAE2, and the second gate insulating film 132 disposed between them.

A first interlayer insulating film 141 may be disposed on the second capacitor electrode CAE2.

A first data metal layer may be disposed on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the interlayer insulating film 141.

A first planarization organic film 160 may be disposed on the first source connection electrode PCE1 to planarize a step caused by the thin film transistor TFT1.

A second data metal layer may be disposed on the first planarization organic film 160. The second data metal layer may include a second source connection electrode PCE2. The second source connection electrode PCE2 may be connected to the first source connection electrode PCE1 through a second pixel contact hole PCT2 penetrating the first planarization organic film 160.

A first via layer 181 may be disposed on the second source connection electrode PCE2.

A second via layer 182 and a pixel electrode PXE may be disposed on the first via layer 181.

The barrier film BR, the first gate insulating film 131, the second gate insulating film 132, the third gate insulating film 133, and the interlayer insulating film 141 may be formed of an inorganic film, for example, silicon nitride (SiNₓ), silicon oxide (SiON), silicon oxide (SiOₓ), titanium oxide (TiOₓ), or aluminum oxide (AlOₓ).

The first gate metal layer, the second gate metal layer, the first data metal layer, and the second data metal layer may be formed as a single layer or multiple layers of any one of molybdenum (Mo), aluminum (Al), chromium (Cr), gold (Au), titanium (Ti), nickel (Ni), neodymium (Nd), and copper (Cu), or an alloy thereof.

The first planarization organic film 160, the first via layer 181, and the second via layer 182 may be formed of an organic insulating film such as an acrylic resin, an epoxy resin, a phenolic resin, a polyamide resin, or a polyimide resin.

Since the first via layer 181 also plays a role in planarizing the step caused by the second source connection electrode PCE2, it may also be called a planarization layer.

A pixel electrode layer may be disposed on the first via layer 181.

The pixel electrode layer may include a first pixel electrode PXE1, a second pixel electrode PXE2, and a third pixel electrode PXE3. Each of the pixel electrodes PXE1, PXE2, and PXE3 may be connected to a second source connection electrode PCE2 through a connection hole (CT1/CT2/CT3 of FIG. 5) penetrating the first via layer 181. Each of the pixel electrodes PXE1, PXE2, and PXE3 may be connected to a first source region S1 or a first drain region D1 of a thin film transistor TFT1 through the first source connection electrode PCE1 and the second source connection electrode PCE2. Thus, a voltage controlled by the thin film transistor TFT1 may be applied to each of the pixel electrodes PXE1, PXE2, and PXE3.

The pixel electrodes PXE1, PXE2, and PXE3 may be formed of a single layer or multiple layers made of one or an alloy of molybdenum (Mo), aluminum (Al), chromium (Cr), gold (Au), titanium (Ti), nickel (Ni), neodymium (Nd), and copper (Cu). For example, the pixel electrode layer may be made of copper (Cu) having low surface resistance to lower the resistance of each of the pixel electrodes PXE1, PXE2, and PXE3. Further, the pixel electrodes PXE1, PXE2, and PXE3 may include a first layer made of one or an alloy of molybdenum (Mo), aluminum (Al), chromium (Cr), gold (Au), titanium (Ti), nickel (Ni), neodymium (Nd), and copper (Cu) at the bottom, and a second layer made of a metal material having a high reflectivity, such as aluminum (Al), on the first layer, when the pixel electrodes PXE1, PXE2, and PXE3 are formed in a multilayer structure.

The pixel electrode layer may include a protective film PF surrounding each side of the pixel electrodes PXE1, PXE2, and PXE3. The protective film TPF may be referred to as a sacrificial layer as a film to protect the pixel electrodes PXE1, PXE2, and PXE3 during the organic partition wall BWL process. After the protective film TPF is formed to cover both the top surfaces and the side surfaces of the pixel electrodes PXE1, PXE2, and PXE3, the protective film TPF disposed on the top surfaces of the pixel electrodes PXE1, PXE2, and PXE3 is removed, leaving only the side surfaces of the pixel electrodes PXE1, PXE2, and PXE3. Accordingly, the protective film TPF surrounds the side surfaces of the pixel electrodes PXE1, PXE2, and PXE3 and exposes upper portions of the pixel electrodes PXE1, PXE2, and PXE3. The upper portions of the pixel electrodes PXE1, PXE2, and PXE3 are the surface on which the light-emitting element LE is subsequently arranged. The protective film TPF may be formed of an oxide metal such as ITO (Indium Tin Oxide), IGZO (Indium Gallium Zinc Oxide), and IZO (Indium Zinc Oxide) but is not necessarily limited thereto.

Referring to FIGS. 7 to 10, a second via layer 182 may be further disposed on the first via layer 181.

The second via layer 182 may have a flat top surface. The second via layer 182 may cover the entire surface of the first via layer 181 except for the area where the pixel electrode layer is disposed. In the area where the pixel electrode layer is disposed, the second via layer 182 has a via layer opening OP1 that exposes the pixel electrode PXE and the protective film TPF. The area exposed by the via layer opening OP1 may be wider than the area of the light-emitting element LE.

The via layer opening OP1 may expose not only the pixel electrode PXE and the protective film TPF but also the first via layer 181 around the pixel electrode PXE and the protective film TPF in the third direction DR3. The first via layer 181 may have a recessed groove 181-h in the exposed area around the pixel electrode PXE and the protective film TPF. The exposed area around the pixel electrode PXE and the passivation film TPF has a lower thickness than the other areas of the first via layer 181. In another modified example, the recessed groove 181-h of the first via layer 181 may be omitted.

The second via layer 182 may be composed of the same material as the first via layer 181. The second via layer 182 may include an organic insulating material such as polyacrylates resin, epoxy resin, phenolic resin, polyamides resin, polyimides rein, unsaturated polyesters resin, poly phenyleneethers resin, polyphenylenesulfides resin, or benzocyclobutene (BCB).

An organic partition wall BWL may be disposed on the second via layer 182.

The organic partition wall BWL has a structure in which the width narrows toward the top. The organic partition wall BWL may be formed on the second via layer 182 at a first height h1. The top surface of the organic partition wall BWL may be positioned lower than the top surface of the light-emitting element LE. The first height h1 may be about 5 μm to 8 μm but is not necessarily limited thereto. When the upper end of the organic partition wall BWL is formed lower than the light-emitting element LE, it has an advantage in that the light-emitting element LE may be easily transferred during the light-emitting element LE transfer process.

The organic partition wall BWL may have a closed loop shape that surrounds the side of the light-emitting element LE while being spaced apart from the light-emitting element LE on a plane. The bottom surface of the organic partition wall BWL may be a surface that contacts the second via layer 182 and the top surface may be a surface facing the bottom surface. An angle θ-B between the outer surface of the organic partition wall BWL and the reference plane may be about 120 degrees to 135 degrees. In an embodiment, it may be about 125 degrees. Here, the reference plane may be an extended surface of the surface including the contact surface of the light-emitting element and the bonding electrode, for example, the lowermost end of the light-emitting element LE. The organic partition wall BWL may be formed more gently as the angle between the outer surface and the reference surface increases.

The organic partition wall BWL may be formed of an organic material such as an acrylic resin, an epoxy resin, a phenolic resin, a polyamide resin, or a polyimide resin.

A first insulating film INS1 is disposed on the outside of the organic partition wall BWL. The first insulating film INS1 may cover both the side surface and the top surface of the organic partition wall BWL. The first insulating film INS1 may extend along the side surface of the via layer 182 exposed by the via layer opening OP1 from the side surface of the organic partition wall BWL. In addition, the first insulating film INS1 may extend from the side of the via layer 182 to cover the upper portion of the first via layer 181 exposed by the via layer opening OP1 and may cover the protective film TPF. The first insulating film INS1 may have a first protrusion portion INS1-P protruding from the upper portion of the protective film TPF in the second direction DR2. The first protrusion portion INS1-P may overlap a portion of the pixel electrode layer in the third direction DR3. For example, the first protrusion portion INS1-P may overlap the protective film TPF in the third direction DR3 and may overlap a portion of the pixel electrode PXE1, PXE2, and PXE3, for example, an edge and the third direction DR3, but is not necessarily limited thereto.

The first protrusion portion INS1-P may have a bottom surface INS1-P-B facing the first via layer 181 and a top surface INS1-P-T facing the bottom surface INS1-P-B by protruding from the upper portion of the protective film TPF in the second direction DR2. The first protrusion portion INS1-P overlaps the pixel electrode PXE1, PXE2, and PXE3 in the third direction DR3, but is spaced apart from each other in the third direction DR3. A bonding electrode BOE is disposed between the bottom surface INS1-P-B of the first protrusion portion INS1-P and the top surface of the pixel electrode PXE1, PXE2, and PXE3, and the bottom surface INS1-P-B and the pixel electrode PXE1, PXE2, and PXE3 are spaced apart from each other by the bonding electrode BOE.

A reflective film RF is disposed outside of the first insulating film INS1. The reflective film RF is disposed outside of the first insulating film INS1. The reflective film RF is disposed on the first insulating film INS1.

The reflective film RF is disposed on the first insulating film INS1, covers both the side surface and the top surface of the organic partition wall BWL, and extends along the side surface of the via layer 182 exposed by the via layer opening OP1 from the side surface of the organic partition wall BWL.

The reflective film RF may be disposed on the entire surface of the pixel area excluding the area where the light-emitting element LE has a planar shape.

Since the reflective film RF has a constant thickness on the top surface of the organic partition wall BWL, it may have the same inclination angle as the inclination angle of the organic partition wall BWL. Thus, the angle formed between the outer surface of the reflective film RF and the reference surface has an inclination angle of about 120 to 135 degrees. In an embodiment, the angle formed between the outer surface of the reflective film RF and the reference plane may be about 125 degrees.

In addition, the reflective film RF may extend from the side surface of the via layer 182 on the top surface of the first insulating film INS1 to cover the upper portion of the first via layer 181 exposed by the via layer opening OP1 and may cover the protective film TPF. The reflective film RF may have a second protrusion portion RF-P protruding in the second direction DR2 from the upper portion of the protective film TPF. The second protrusion portion RF-P may overlap a portion of the pixel electrode layer in the third direction DR3. For example, the second protrusion portion RF-P may overlap the protective film TPF in the third direction DR3 and may overlap a portion of the pixel electrode PXE1, PXE2, and PXE3, for example, an edge, in the third direction DR3. The side surface of the second protrusion portion RF-P and the side surface of the first protrusion portion INS1-P may be aligned with each other. The bottom surface of the reflective film RF is a surface that contacts the first insulating film INS1, and the top surface is a surface facing the bottom surface.

The reflective film RF may include a metal material having high reflectivity. The reflective film RF may be aluminum (Al) but is not necessarily limited thereto.

Since the reflective film RF reflects light traveling in a direction other than the front surface from the light-emitting element LE, and the top of the pixel electrodes PXE1, PXE2, and PXE3 also includes a reflective film, substantially, the pixel area is substantially provided with the reflective film on the entire surface in a plane. Since the reflective film is disposed on the entire surface of the pixel area, light may be emitted to the top surface of the light-emitting element LE. Therefore, since the loss of light from the light-emitting element LE may be reduced, the light emission efficiency of the light-emitting element LE may be increased.

A second insulating film INS2 is disposed on the top surface of the reflective film RF. The second insulating film INS2 covers the entire reflective film RF. Therefore, the reflective film RF is surrounded by the first insulating film INS1 and the second insulating film INS2.

The second insulating film INS2 is disposed on the top surface of the reflective film RF, covers both the side surface and the top surface of the organic layer 190, and extends along the side surface of the via layer 182 exposed by the via layer opening OP1 from the side surface of the organic partition wall BWL.

The second insulating film INS2 may be disposed on the entire surface of the pixel area excluding the area where the light-emitting element LE has a planar surface.

The second insulating film INS2 may extend from the side surface of the via layer 182 on the top surface of the reflective film RF to cover the upper portion of the first via layer 181 exposed by the via layer opening OP1 and may cover the protective film TPF. The second insulating film INS2 may have a third protrusion portion INS2-P that protrudes in the second direction DR2 from an upper portion of the protective film TPF. The third protrusion portion INS2-P may overlap a portion of the pixel electrode layer in the third direction DR3. For example, the third protrusion portion INS2-P may overlap the protective film TPF in the third direction DR3 and may overlap a portion of the pixel electrode PXE1, PXE2, and PXE3, for example, an edge, in the third direction DR3. The third protrusion portion INS2-P may protrude further in the second direction DR2 than the first protrusion portion INS1-P and the second protrusion portion RF-P and may completely surround the second protrusion portion RF-P. Thus, the reflective film RF may be completely surrounded by the first insulating layer INS1 and the second insulating layer INS2. The bottom surface of the second insulating layer INS2 is a surface in contact with the reflective film RF, and the top surface is a surface that faces the bottom surface.

An area where at least one of the protrusion portion INS1-P of the first insulating film INS1, the protrusion portion RF-P of the reflective film RF, and the protrusion portion INS2-P of the second insulating film INS2 overlaps in the thickness direction may be referred to as a protrusion area.

The first insulating film INS1 and the second insulating film INS2 may be formed of an inorganic film, for example, silicon nitride (SiNₓ), silicon oxide (SiON), silicon oxide (SiOₓ), titanium oxide (TiOₓ), or aluminum oxide (AlOₓ).

A plurality of light-emitting elements LE may be disposed on pixel electrodes PXE1, PXE2, and PXE3. In FIGS. 6 and 7, each of the plurality of light-emitting elements LE is illustrated as a vertical type micro LED extending in the third direction DR3. A vertical type micro LED refers to an LED having a structure in which a first semiconductor layer SEM1, an active layer MQW, and a second semiconductor layer SEM2 are sequentially disposed in the third direction DR3 which is a vertical direction.

Each of the plurality of light-emitting elements LE may be formed of an inorganic material such as gallium nitride (GaN). Each of the plurality of light-emitting elements LE may have a length in the first direction DR1, a length in the second direction DR2, and a length in the third direction DR3 of several to several hundred μm, respectively. For example, each of the plurality of light-emitting elements LE may have a length in the first direction DR1, a length in the second direction DR2, and a length in the third direction DR3 of approximately 6 μm to 10 μm or less.

Each of the plurality of light-emitting elements LE may be formed by growing on a semiconductor substrate such as a silicon substrate or a sapphire substrate. The plurality of light-emitting elements LE may be transferred directly from the semiconductor substrate onto the pixel electrodes PXE1, PXE2, and PXE3 of the display panel 100. Alternatively, the plurality of light-emitting elements LE may be transferred onto the pixel electrodes PXE1, PXE2, and PXE3 of the display panel 100 by an electrostatic method using an electrostatic head or a stamp method using an elastic polymer material such as PDMS or silicon as a transfer substrate.

The conductive layer E1, the first semiconductor layer SEM1, the active layer MQW, and the second semiconductor layer SEM2 may be referred to as element rod.

The element rod may include a first element rod LD1 and a second element rod LD2.

The first element rod LD1 may include a first side wall SS1 having a first taper angle θ1. The first taper angle θ1 of the first side wall SS1 may be 70 degrees or more and less than 90 degrees.

The first element rod LD1 may include a conductive layer E1, a first semiconductor layer SEM1, and an active layer MQW.

In an embodiment, the conductive layer E1 may be disposed on the bottom surface of the first semiconductor layer SEM1. In FIG. 7, the conductive layer E1 is illustrated as covering the entire bottom surface of the first semiconductor layer SEM1, but the embodiment of the present disclosure is not necessarily limited thereto. For example, the conductive layer E1 may be disposed on a portion of the bottom surface of the first semiconductor layer SEM1. The conductive layer E1 may include one of molybdenum (Mo), aluminum (Al), chromium (Cr), gold (Au), titanium (Ti), nickel (Ni), neodymium (Nd), and copper (Cu).

The first semiconductor layer SEM1 may be disposed on the conductive layer E1. The first semiconductor layer SEM1 may be formed of a semiconductor material layer doped with a first conductive dopant such as magnesium (Mg), zinc (Zn), calcium (Ca), strontium (Sr), barium (Ba), etc., for example, gallium nitride (GaN).

The active layer MQW may be disposed on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. At this time, the well layer may be formed of indium gallium nitride (InGaN), and the barrier layer may be formed of gallium nitride (GaN) or aluminum gallium nitride (AlGaN), but embodiments of the present disclosure are not necessarily limited thereto.

Alternatively, the active layer MQW may have a structure in which semiconductor materials having a high band gap energy and semiconductor materials having a low band gap energy are alternately stacked with each other, may include other Group three to five semiconductor materials according to the wavelength range of emitted light.

In an embodiment, when the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light-emitting element LE that emits the third light (light in the blue wavelength band) may be approximately 10 wt % to 20 wt %.

The second element rod LD2 is disposed on the first element rod LD1 and may include a second semiconductor layer SEM2.

The ratio of the height h11 of the first element rod LD1 and the height h21 of the second element rod LD2 may be 1:2. For example, the height h21 of the second element rod LD2 may be about twice the height h1 of the first element rod LD1.

The second element rod LD2 may include a second side wall SS2 having a second taper angle θ2. The second taper angle θ2 of the second side wall SS2 may be 60 degrees or more and 80 degrees or less. Further, the second taper angle θ2 may be smaller than the first taper angle θ1. Therefore, the second side wall SS2 may be formed with a regular taper. The second element rod LD2 becomes wider as it gets further away from the first element rod LD1.

The second element rod LD2 may include a second semiconductor layer SEM2.

The second semiconductor layer SEM2 may be disposed on the first semiconductor layer SEM1. The second semiconductor layer SEM2 may be a semiconductor material layer doped with a second conductivity type dopant such as silicon (Si), germanium (Ge), tin (Sn), etc., for example, gallium nitride (GaN).

An electron blocking layer may be disposed between the first semiconductor layer SEM1 and the active layer MQW. The electron blocking layer may be a layer to suppress or prevent too many electrons from flowing into the active layer MQW. For example, the electron blocking layer may be aluminum gallium nitride (AlGaN) or p-type aluminum gallium nitride (AlGaN) doped with p-type magnesium (Mg). The electronic blocking layer may be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or p-type aluminum gallium nitride (AlGaN) doped with p-type magnesium (Mg). The superlattice layer may be omitted.

The shape of the light-emitting element LE may vary depending on the embodiments. The light-emitting element LE may have a substantially inverted tapered cross-sectional shape. For example, the light-emitting element LE may have a inverted tapered cross-sectional shape in which the width of the top surface is wider than the width of the bottom surface. The light-emitting element LE may include vertical side surfaces. For example, the light-emitting element LE may be patterned through vertical etching and may have a rectangular or square cross-sectional shape in which the width of the top surface and the width of the bottom surface are substantially the same.

The light-emitting element LE may further include a contact electrode CTE, and an element protective layer INS.

The element protective layer INS may be a film for protecting the bottom surface and the side surface of the light-emitting element LE. The element protective layer INS may be disposed on the bottom surface and the side surface of the conductive layer E1, and the side surface of the element rods LD1 and LD2. For example, the element protective layer INS may be disposed on the bottom surface and side surface of the conductive layer E1, the side surface of the first semiconductor layer SEM1, the side surface of the active layer MQW, and the side surface of the second semiconductor layer SEM2. The element protective layer INS may be formed of an inorganic film, such as silicon nitride (SiNₓ), silicon oxide nitride (SiON), silicon oxide (SiOₓ), titanium oxide (TiOₓ), or aluminum oxide (AlOₓ).

The contact electrode CTE may be disposed on the protective layer INS. The contact electrode CTE may be disposed between the pixel electrodes PXE1, PXE2, and PXE3 and the protective layer INS. The contact electrode CTE may be in contact with the pixel electrodes PXE1, PXE2, and PXE3.

The contact electrode CTE may be connected to the conductive layer E1 that is exposed and not covered by the protective layer INS.

The contact electrode CTE may include one of molybdenum (Mo), aluminum (Al), chromium (Cr), gold (Au), titanium (Ti), nickel (Ni), neodymium (Nd), and copper (Cu). For example, the plurality of contact electrodes CTE may be formed as a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

The bonding electrode BOE may be disposed between the pixel electrodes PXE1, PXE2, and PXE3 and the contact electrode CTE of the corresponding light-emitting element LE. The bonding electrode BOE may serve as a bonding metal for bonding the pixel electrodes PXE1, PXE2, and PXE3 and the corresponding light-emitting elements LE. For example, the bonding electrodes BOE may include at least one of gold (Au), copper (Cu), tin (Sn), silver (Ag), aluminum (Al), and titanium (Ti). For example, the bonding electrodes BOE can include a 9:1 alloy of gold and tin, an 8:2 alloy, or a 7:3 alloy.

The third organic layer 211 may cover the side surfaces of the plurality of light-emitting elements LE and the second insulating layer INS2.

The third organic layer 211 is a layer for flattening the steps caused by the lower structures including the plurality of light-emitting elements LE and the organic partition wall BWL. The height of the third organic layer 211 may cover most of the side surfaces of each of the plurality of light-emitting elements LE, but in an embodiment, it may cover the side surfaces of each of the plurality of light-emitting elements LE by a plurality of organic films.

The third organic layer 211 may be formed of an organic material such as an acrylic resin, an epoxy resin, a phenolic resin, a polyamide resin, or a polyimide resin.

The common electrode CE may be disposed on the top surface of each of the plurality of light-emitting elements LE.

The common electrode CE may be a common layer commonly formed in the first sub-pixel SPX1, the second sub-pixel SPX2, and the third sub-pixel SPX3. The common electrode CE may be made of a transparent conductive material (TCO), such as indium tin oxide (ITO) and indium zinc oxide (IZO), which can transmit light.

The pixel electrodes PXE1, PXE2, and PXE3 may be referred to as anode electrodes or first electrodes, and the common electrode CE may be referred to as cathode electrodes or second electrodes.

The first capping layer CAP1 may be disposed on the common electrode CE. The first capping layer CAP1 may serve to encapsulate the underlying component.

The first capping layer CAP1 may be formed of an inorganic film, such as silicon nitride (SiNₓ), silicon oxide nitride (SiON), silicon oxide (SiOₓ), titanium oxide (TiOₓ), or aluminum oxide (AlOₓ).

A fourth organic layer 213 may be disposed on the first capping layer CAP1. A plurality of color filters CF1, CF2, and CF3 may be disposed on the fourth organic layer 213. The plurality of color filters CF1, CF2, and CF3 may include first color filters CF1, second color filters CF2, and third color filters CF3.

The first color filter CF1 disposed in the first sub-pixel SPX1 may transmit the first light (light in the red wavelength band). Thus, the first sub-pixel SPX1 may emit the first light (light in the red wavelength band).

The second color filter CF2 disposed in the second sub-pixel SPX2 may transmit the second light (light in the green wavelength band). Thus, the second sub-pixel SPX2 may emit the second light (light in the green wavelength band).

The third color filter CF3 disposed in the third sub-pixel SPX3 may transmit the third light (light in the blue wavelength band). Thus, the third sub-pixel SPX3 may emit the third light (light of a blue wavelength band).

The first color filter CF1, the second color filter CF2, and the third color filter CF3 overlapping in the third direction DR3 may overlap the organic partition wall BWL in the third direction DR3.

A fifth organic layer 214 for planarization may be disposed on the plurality of color filters CF1, CF2, and CF3.

The third organic film 213 and the fifth organic layer 214 may be formed from an acrylic resin, an epoxy resin, a phenolic resin, a polyamide resin, a polyimide resin, or the like.

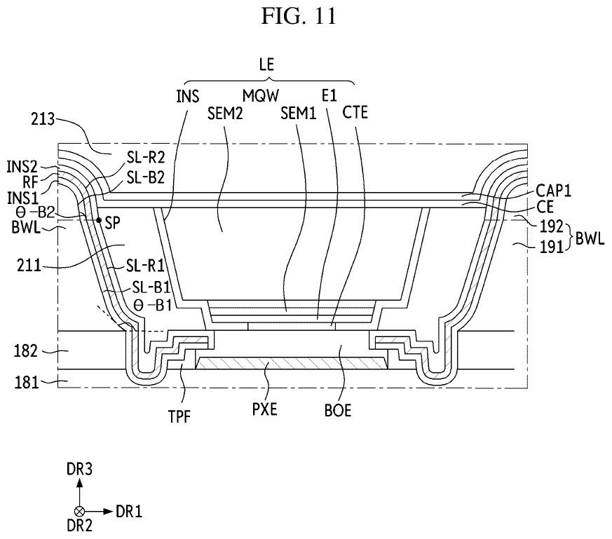

FIG. 11 is a cross-sectional view illustrating an example of the A area of FIG. 6 in detail.

The embodiment of FIG. 11 differs from the embodiment of FIG. 7 in that the organic partition wall BWL includes a first organic layer 191 and a second organic layer 192. In FIG. 11, to the extent that an element is not described in detail with respect to this figure, it may be understood that the element is at least similar to a corresponding element that has been described elsewhere within the present disclosure, such as with respect to FIG. 7.

Referring to FIG. 11, the organic partition wall BWL may include a first organic layer 191 and a second organic layer 192 disposed on the first organic layer 191.

The first organic layer 191 and the second organic layer 192 have different inclinations.

A first angle θ-B1 of the outer surface SL-B1 of the first organic layer 191 may be greater than a second angle θ-B2 of the outer surface of the second organic layer 192. For example, the first angle of the first organic layer 191 may be 120 degrees or more, and the second angle of the second organic layer 192 may be 120 degrees or less. The average of the angle of the outer surface SL-B1 of the first organic layer 191 and the angle of the outer surface SL-B2 of the second organic layer 192 may be about 120 degrees to 135 degrees.

The contact surface of the first organic layer 191 and the second organic layer 192 may be located higher than the contact surface of the active layer MQW and the second semiconductor layer SEM2 of the light-emitting element LE. Thus, the top surface of the active layer MQW may be lower than the top surface of the first organic layer 191. The top surface of the first organic layer 191 is the surface that contacts the second organic layer 192, and the bottom surface is the surface that faces the top surface. The top surface of the active layer MQW is the surface that contacts the second semiconductor layer SEM2, and the bottom surface is the surface facing the top surface.

Since the first organic layer 191 and the second organic layer 192 have a three-layer structure of a first insulating film INS1, a reflective film RF, and a second insulating film INS2 on (outside) the first organic layer 191 and the second organic layer 192, for convenience of explanation, the reflective film RF disposed on the outside of the first organic layer 191 is referred to as the first reflective film, and the reflective film RF disposed on the outside of the second organic layer 192 is referred to as the second reflective film. Furthermore, the angle of the outer surface SL-R1 of the first reflective film is the same as the angle of the outer surface of the first organic layer 191, and the angle of the outer surface SL-R2 of the second reflective film is the same as the angle of the outer surface of the second organic layer 192.

Therefore, the average angle of the angle of the outer surface SL-R1 of the first reflective film and the angle of the outer surface SL-R 2 of the second reflective film is 120 degrees or more, preferably 120 to 135 degrees. Furthermore, the angle of this outer surface SL-R 1 of the first reflective film is greater than the angle of the outer surface SL-R2 of the second reflective film. For example, the angle of this outer surface SL-R 1 of the first reflective film may be 120 degrees or more, and the angle of the outer surface SL-R2 of the second reflective film may be 120 degrees or less.

In addition, the inflection point SP at which the angle of the outer surface SL-R1 of the first reflective film and the outer surface SL-R2 of the second reflective film abruptly changes may be located higher than the top surface of the active layer MQW of the light-emitting element LE. Thus, the top surface of the active layer MQW may be located lower than the top surface of the first reflective film.

In an embodiment, when the top surface of the organic partition wall BWL is formed higher than the top surface of the light-emitting element LE, the reflective film RF disposed on the outside of the organic partition wall BWL is positioned higher than the top surface of the light-emitting element LE, which is advantageous in that the light-emitting efficiency of the light-emitting element LE may be increased.

In the embodiments of FIGS. 6 to 11, the organic partition wall BWL is formed as a single layer or two layers but is not necessarily limited thereto. For example, the organic partition wall BWL may be formed as a three-layer organic layer. Even when formed as a three-layer organic layer, the organic partition wall BWL may have a shape in which the width becomes narrower as it goes upward.

In the display device according to various embodiments, there is no reflective film directly disposed on the outside of the light-emitting element LE, and the bottom of the reflective film RF in the organic partition wall BWL is positioned lower than the bottom of the light-emitting element LE, so that the organic partition wall BWL may effectively reflect the side light of the light-emitting element LE. Directly disposed on the outside of the light-emitting element LE may mean a reflective film contacting the element protective layer INS of the light-emitting element LE.

Although the display device in the embodiment of FIG. 6 does not include a wavelength conversion layer, in various modifications, a wavelength conversion layer may be included between the color filter and the capping layer CAP1. The wavelength conversion layer may transmit only a specific wavelength among the incident light. For example, a first wavelength conversion layer that transmits only light of the first wavelength band may be disposed on a first light-emitting element that emits light of the first wavelength band, and a second wavelength conversion layer that transmits only light of the second wavelength band may be disposed on a second light-emitting element that emits light of the second wavelength band.

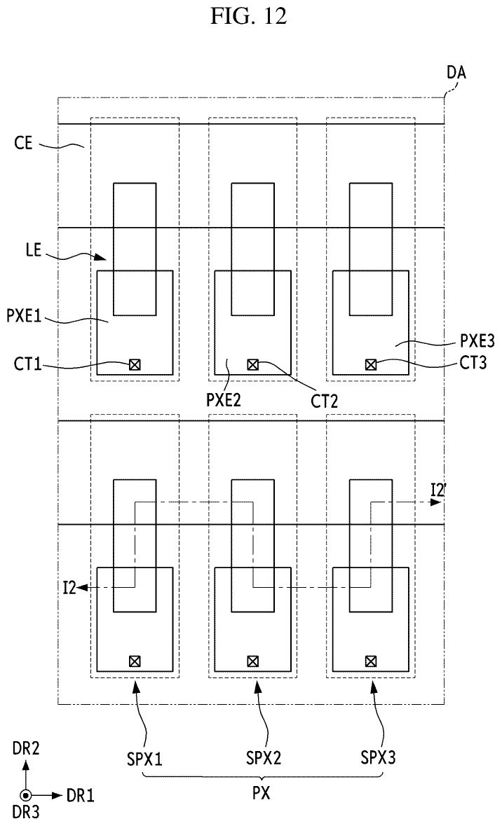

FIG. 12 is a layout diagram illustrating pixels of a display area according to an embodiment.

The embodiment of FIG. 12 differs from the embodiment of FIG. 5 in that the light-emitting elements LE are disposed on the pixel electrodes PXE1, PXE2, and PXE3 and the common electrode CE in each of the first sub-pixel SPX1, the second sub-pixel SPX2, and the third sub-pixel SPX3. In FIG. 12, to the extent that an element is not described in detail with respect to this figure, it may be understood that the element is at least similar to a corresponding element that has been described elsewhere within the present disclosure, such as with respect to FIG. 5.

Referring to FIG. 12, the pixel electrodes PXE1, PXE2, and PXE3 and the common electrode CE in each of the first sub-pixel SPX1, the second sub-pixel SPX2, and the third sub-pixel SPX3 may be arranged in the second direction DR2. Each of the pixel electrodes PXE1, PXE2, and PXE3 and the common electrodes CE may have a rectangular planar shape, but the embodiment of the present disclosure is not necessarily limited thereto.

In each of the first sub-pixel SPX1, the second sub-pixel SPX2, and the third sub-pixel SPX3, the pixel electrodes PXE1, PXE2, and PXE3 and the common electrode CE and the light-emitting element LE are disposed on the pixel electrodes PXE1, PXE2, and PXE3 and the common electrode CE, so that the length of the light-emitting element LE in the second direction DR2 may be longer than the length in the first direction DR1.

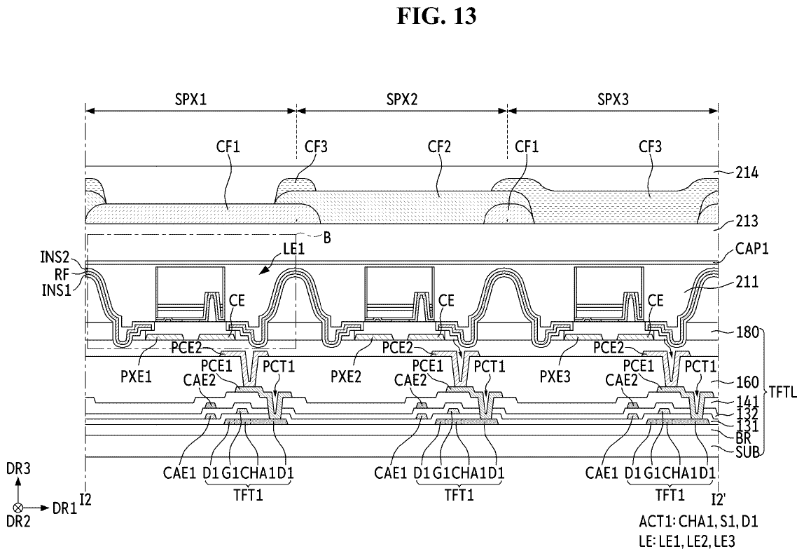

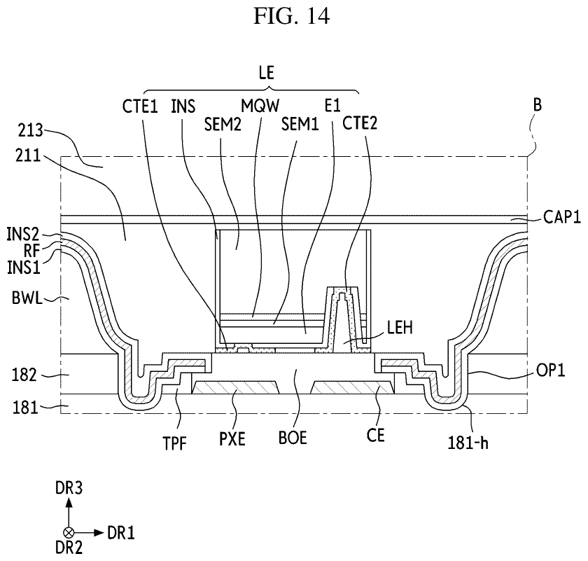

FIG. 13 is a cross-sectional view illustrating an example of a cross-section of a display panel corresponding to line I2-I2′ in FIG. 11. FIG. 14 is a cross-sectional view illustrating an example of the B area of FIG. 13 in detail.

The embodiments of FIGS. 13 and 14 differ from the embodiments of FIGS. 6 and 7 in that the light-emitting element LE is a flip type micro LED and the common electrode is included in the pixel electrode layer. In FIGS. 13 and 14, to the extent that an element is not described in detail with respect to this figure, it may be understood that the element is at least similar to a corresponding element that has been described elsewhere within the present disclosure, such as with respect to FIGS. 6 and 7.

Referring to FIGS. 13 and 14, a pixel electrode layer may be disposed on a first via layer 181. The pixel electrode layer may include pixel electrodes PXE1, PXE2, and PXE3 and a common electrode CE, and may further include a protective film TPF surrounding the side surfaces of the pixel electrodes PXE1, PXE2, and PXE3 and the side surfaces of the common electrode CE. The protective film TPF may also be disposed between the common electrode CE and the pixel electrodes PXE1, PXE2, and PXE3 corresponding to the common electrode.

A light-emitting element LE may be disposed on the first via layer 181. The light-emitting element LE may be a flip-type micro LED. The flip-type micro LED refers to an LED in which contact electrodes CTE1 and CTE2 are formed on one surface (e.g., the bottom surface) of the light-emitting element LE. A first contact electrode CTE1 may be disposed on the pixel electrodes PXE1, PXE2, and PXE3 and a second contact electrode CTE2 may be disposed on the common electrode CE.

A bonding electrode BOE may be disposed between the first via layer 181 and the light-emitting element LE. The bonding electrode BOE may be disposed between the pixel electrodes PXE1, PXE2, and PXE3 and the first contact electrode CTE1 of the corresponding light-emitting element LE, and between the common electrode CE and the second contact electrode CTE2 of the corresponding light-emitting element LE. The bonding electrode BOE may serve as a bonding metal for bonding the pixel electrodes PXE1, PXE2, and PXE3 and the corresponding light-emitting element LE.

Referring to FIG. 14, the light emitting element LE may include a conductive layer E1, a first semiconductor layer SEM1, an active layer MQW, an element protective layer INS, a first contact electrode CTE1, and a second contact electrode CTE2. Further, the light-emitting element LE may have a hole LEH penetrating the conductive layer E1, the first semiconductor layer SEM1, and the active layer MQW to expose the second semiconductor layer SEM2. The hole LEH may have a circular planar shape, but the embodiment of the present disclosure is not necessarily limited thereto. For example, the hole LEH may have a polygonal planar shape, such as an oval or a square.

In addition, the element protective layer INS may be disposed on the sidewall of the conductive layer E1 exposed by the hole LEH, the sidewall of the first semiconductor layer SEM1, the sidewall of the active layer MQW, and the sidewall of the second semiconductor layer SEM2. The element protective layer INS may not cover the second semiconductor layer SEM2 in the hole LEH.

The first contact electrode CTE1 may be disposed on one surface of the conductive layer E1. Thus, the first contact electrode CTE1 may be electrically connected to the conductive layer E1.

The second contact electrode CTE2 may be disposed on one surface of the conductive layer E1 at a distance from the first contact electrode CTE1. The second contact electrode CTE2 may be disposed on the element protective film INS disposed in the hole LEH and the second semiconductor layer SEM2 exposed in the hole LEH without being covered by the element protective film INS. Thus, the second contact electrode CTE2 may be electrically connected to the second semiconductor layer SEM2 in the hole LEH.

A second via layer 182 may be further disposed on the first via layer 181.

The second via layer 182 may have a flat top surface. The second via layer 182 may cover the entire surface of the first via layer 181 except for the area where the pixel electrode layer is disposed. In the area where the pixel electrode layer is disposed, the second via layer 182 has a via layer opening OP1 that exposes the pixel electrode PXE, the common electrode CTE, and the protective layer TPF. The area exposed by the via layer opening OP1 may be wider than the area of the light-emitting element LE.

The via layer opening OP1 may expose not only the pixel electrode PXE, the common electrode CE, and the protective layer TPF, but also the first via layer 181 around the pixel electrode PXE and the protective layer TPF in the third direction DR3. The first via layer 181 may have a recessed groove 181-h that is concave downward in the area where the pixel electrode PXE and the protective layer TPF are exposed. The first via layer 181 has a lower thickness in the exposed area around the pixel electrode PXE, the common electrode CTE, and the protective film TPF than in the other areas of the first via layer 181. In other variants, the recessed groove 181-h of the first via layer 181 may be omitted.

An organic partition wall BWL may be disposed on the second via layer 182.

The organic partition wall BWL has a structure in which the width becomes narrower as it goes upward. A first insulating film INS1, a reflective film RF, and a second insulating film INS2 may be disposed outside of the organic partition wall BWL.

The first insulating film INS1, the reflective film RF, and the second insulating film INS2 may have protrusion portions INS1-P, RF-P, and INS2-P that protrude in the second direction DR2 from the upper portion of the protective film TPF. The protrusion portions INS1-P, RF-P, and INS2-P may overlap a portion of the pixel electrode layer in the third direction DR3.

The third organic layer 211 may cover the plurality of light-emitting elements LE.

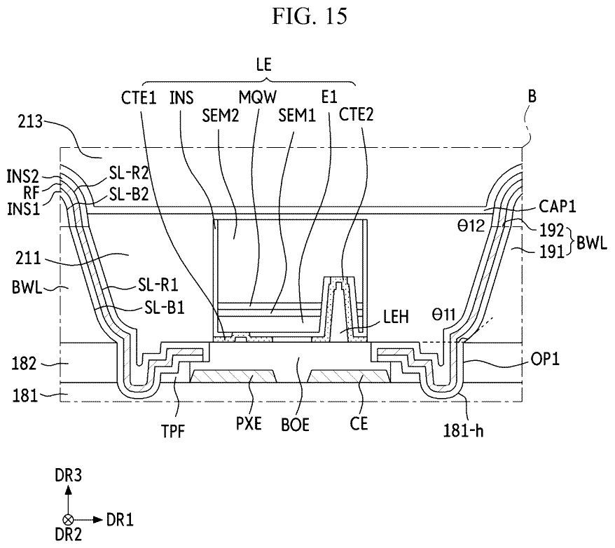

FIG. 15 is a cross-sectional view illustrating an example of area B of FIG. 14 in detail.

The embodiment of FIG. 15 differs from the embodiment of FIG. 14 in that the organic partition wall BWL includes a first organic layer 191 and a second organic layer 192. In FIG. 15, to the extent that an element is not described in detail with respect to this figure, it may be understood that the element is at least similar to a corresponding element that has been described elsewhere within the present disclosure, such as with respect to FIG. 14.

Referring to FIG. 15, the organic partition wall BWL may include a first organic layer 191 and a second organic layer 192 disposed on the first organic layer 191.

The first organic layer 191 and the second organic layer 192 have different inclinations.

A first angle θ11 of the outer surface of the first organic layer 191 may be greater than second angle θ12 of the outer surface of the second organic layer 192. For example, the first angle θ11 of the first organic layer 191 may be 120 degrees or more, and the second angle θ12 of the second organic layer 192 may be 120 degrees or less. The average of the angle θ11 of the outer surface of the first organic layer 191 and the angle θ12 of the outer surface of the second organic layer 192 may be about 120 degrees to 135 degrees.

The contact surface of the first organic layer 191 and the second organic layer 192 may be located higher than the contact surface of the active layer MQW and the second semiconductor layer SEM2 of the light-emitting element LE. Thus, the top surface of the active layer MQW may be lower than the top surface of the first organic layer 191. The top surface of the first organic layer 191 is the surface that contacts the second organic layer 192, and the bottom surface is the surface that faces the top surface. The top surface of the active layer MQW is the surface that contacts the second semiconductor layer SEM2, and the bottom surface is the surface facing the top surface.

Since the first organic layer 191 and the second organic layer 192 have a three-layer structure of a first insulating film INS1, a reflective film RF, and a second insulating film INS2 on (outside) the first organic layer 191 and the second organic layer 192, for convenience of explanation, the reflective film RF disposed on the outside of the first organic layer 191 is referred to as the first reflective film, and the reflective film RF disposed on the outside of the second organic layer 192 is referred to as the second reflective film. Furthermore, the angle θ_R_11 of the outer surface of the first reflective film is the same as the angle of the outer surface of the first organic layer 191, and the angle θ_R_12 of the outer surface of the second reflective film is the same as the angle of the outer surface of the second organic layer 192.

Therefore, the average angle of the angle θ_R_11 of the outer surface of the first reflective film and the angle θ_R_12 of the outer surface of the second reflective film is 120 degrees or more, preferably 120 to 135 degrees. Further, the angle θ_R_11 of the outer surface of the first reflective film is greater than the angle θ_R_12 of the outer surface of the second reflective film. For example, the angle θ_R_11 of the outer surface of the first reflective film may be 120 degrees or more, and the angle θ_R_12 of the outer surface of the second reflective film may be 120 degrees or less.

Furthermore, the inflection point where the angle of the outer surface of the first reflective film and the outer surface of the second reflective film abruptly changes may be located higher than the top surface of the active layer MQW of the light-emitting element LE. Thus, the top surface of the active layer MQW may be positioned lower than the top surface of the first reflective film.

In an embodiment, when the top surface of the organic partition wall BWL is formed higher than the top surface of the light-emitting element LE, the reflective film RF disposed on the outer side of the organic partition wall BWL is positioned higher than the top surface of the light-emitting element LE, which is advantageous in that the light-emitting efficiency of the light-emitting element LE may be increased.

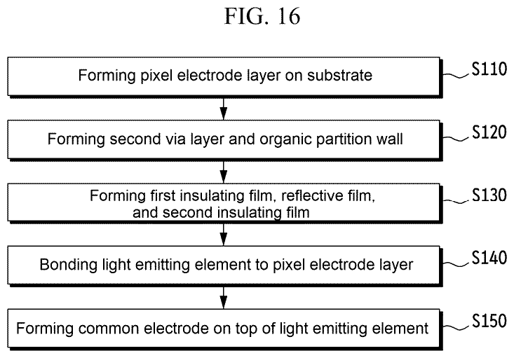

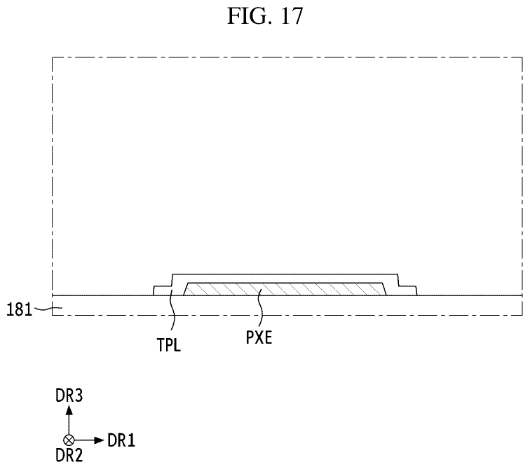

FIG. 16 is a flow chart illustrating a method for manufacturing a display device according to an embodiment. FIGS. 17 to 26 are exemplary drawings to illustrate a method for manufacturing a display device according to an embodiment.

Hereinafter, a method for manufacturing a display device according to an embodiment will be described in detail by connecting FIG. 16 with FIG. 17 to FIG. 26. The method for manufacturing a display device described with reference to FIG. 17 to FIG. 26 may be a display device including a light-emitting element and a display panel described with reference to FIG. 5 to FIG. 7. FIG. 17 to FIG. 26 are cross-sectional views of a display panel corresponding to FIG. 7. In some drawings, a plan view corresponding to the cross-sectional view is also illustrated for convenience of explanation.

First, a pixel electrode layer is formed on a circuit board (S110 in FIG. 16).

As shown in FIG. 16, the circuit board includes a first via layer 181, and a pixel electrode PXE is formed on the first via layer 181. For example, a conductive material layer is entirely deposited on the first via layer 181, a mask pattern is formed on the conductive material layer, and the conductive material layer not covered by the mask pattern is etched. Thereafter, the mask pattern is removed by an ashing process to form a pixel electrode PXE.

Then, a protective layer TPF covering the pixel electrode PXE is formed. The protective layer TPF covers both the top surface and the side surface of the pixel electrode PXE to protect the pixel electrode PXE during the subsequent process.

In an embodiment, as shown in FIGS. 12 and 13, a pixel electrode and a common electrode may be formed as a pixel electrode layer on the first via layer 181. When forming the pixel electrode and the common electrode, the protective layer TPF is formed to cover both the top surface and the side surface of each of the pixel electrode and the common electrode.

Second, a second via layer 182 having a via layer opening OP1 and an organic partition wall BWL are formed (S120 in FIG. 16).

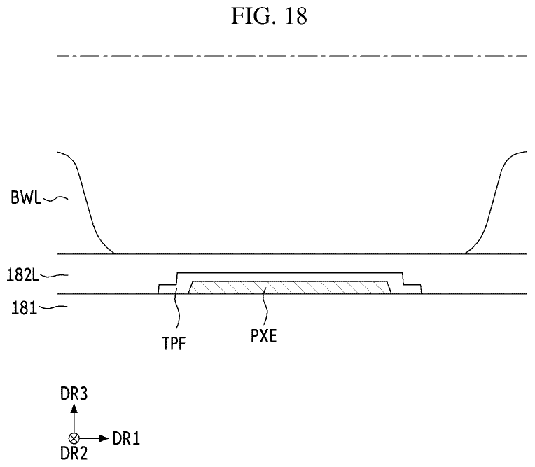

Referring to FIG. 18, an organic material is applied to a certain thickness on the first via layer 181 to form a via material layer 182L.

Then, an organic partition wall BWL is formed on the via material layer. The organic partition wall BWL may be formed by patterning an organic material but is not necessarily limited thereto.

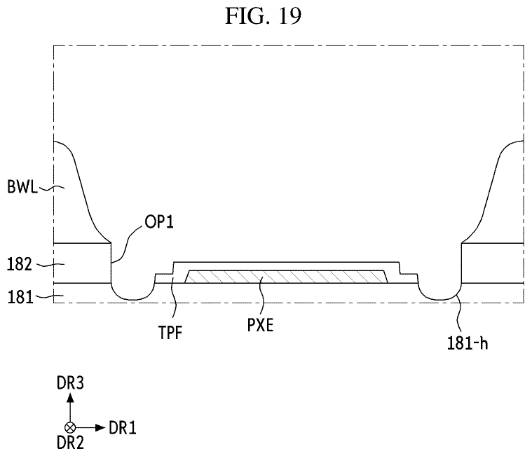

Referring to FIG. 19, after forming a protective film with a photoresist on the organic partition wall BWL, the second via material layer is ashed until the protective film TPF is exposed to form a via layer opening OP1. When the second via material layer is ashed until the protective film TFP is exposed, the second via layer 182 may form a through-hole in the via layer opening OP1, and a recessed groove 181-h may be formed in a portion of the first via layer 181 where the pixel electrode layer is not disposed. By adjusting the degree of ashing, the recessed groove 181-h may not be formed in a portion of the first via layer 181.

In FIGS. 18 and 19, the organic partition wall BWL is formed as a single layer but is not necessarily limited thereto and may be formed as a multi-layer organic layer as shown in FIG. 11. When formed as a multilayer organic layer, a lower organic layer may be formed, and an upper organic layer may be formed on the lower organic layer. When forming a multi-layer organic layer, the average inclination angle of each organic layer may be 120 to 135 degrees.

Third, a first insulating film INS1, a reflective film RF, and a second insulating film INS2 are formed (S130 in FIG. 16).

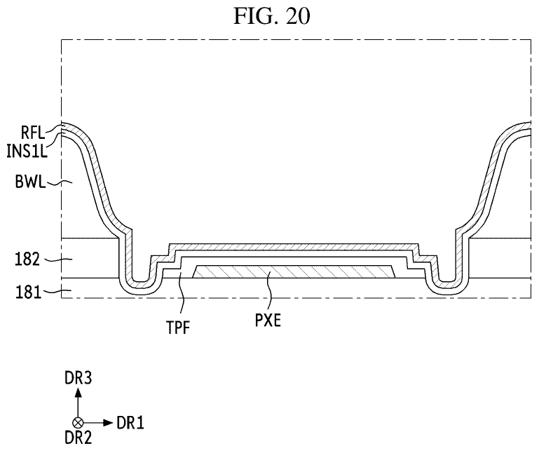

Referring to FIG. 20, an insulating material layer INSL1L is formed on the entire surface of the first via layer 180 of the circuit board. Next, a reflective material layer RFL is deposited on the entire surface of the first via layer 180.

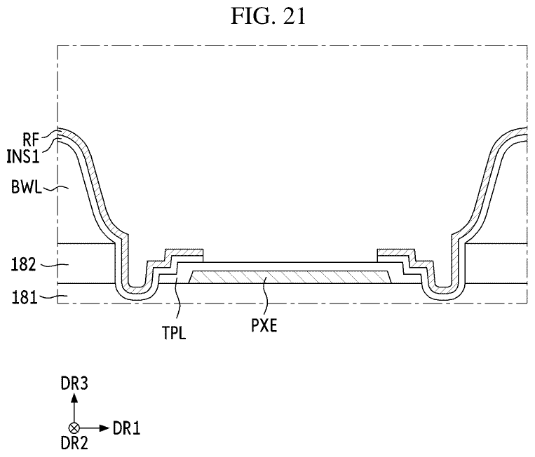

Referring to FIG. 21, the reflective material layer RFL is patterned to expose the protective film TPF, and the reflective material layer and the insulating material layer are etched, thereby forming the first insulating film INS1 and the reflective film RF. The first insulating film INS1 and the reflective film RF may form a protruding area covering the edge of the pixel electrode PXE. When patterning the reflective material layer RFL, the protective film TPF may protect the pixel electrode PXE from the etchant used.

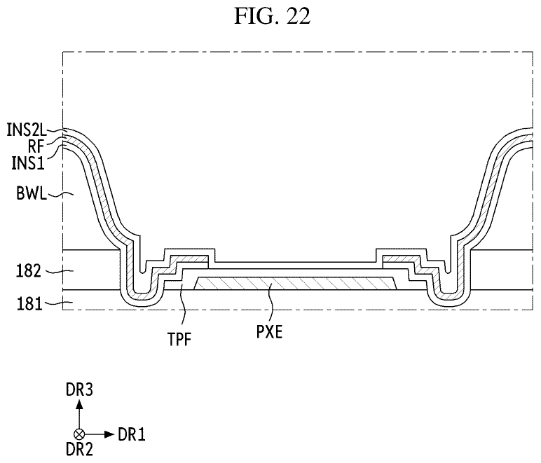

Referring to FIG. 22, an insulating material layer INSL2L is formed on the entire surface of the first via layer 180 of the circuit board. As a result, the reflective film RF may be capped with the insulating material layer INSL2L.

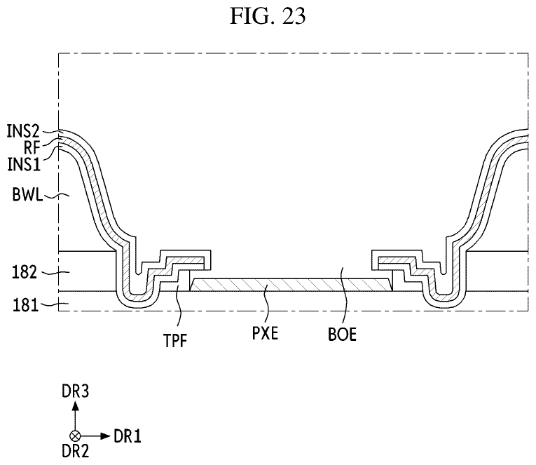

Referring to FIG. 23, the insulating material layer INSL2L is dry etched to form a second insulating film INS2 so that the protective film TPF is exposed. At this time, a dry etchant may be used that etches the insulating material layer INSL2L but does not etch the protective film TPF. The protective film TPF may protect the pixel electrode PXE during dry etching.

Then, the protective film TPF is etched to expose the top surface of the pixel electrode PXE. The etching of the protective film TPF may be performed by wet etching. At this time, since the first insulating layer INS1, the reflective film RF, and the second insulating layer INS2 have a shape that protrudes toward the light-emitting element LE, the protective film TPF disposed under the protrusion portions of the first insulating layer INS1, the reflective film RF, and the second insulating layer INS2 may not be completely removed and may remain as a residual pattern between the pixel electrode PXE and the second via layer 182. Also, at least a portion of the protective film TPF disposed under the protrusion portions of the first insulating layer INS1, the reflective film RF, and the second insulating layer INS2 may be removed, so that a gap may be generated between the first insulating layer INS1 and the pixel electrode PXE.

Fourth, a light-emitting element LE is bonded onto the pixel electrode layer (S140 in FIG. 16).

The light-emitting elements LE may be grown on a semiconductor substrate. The semiconductor substrate may be a silicon wafer substrate or a sapphire substrate.

A plurality of semiconductor layers may be formed on the semiconductor substrate through an epitaxial growth process. As the epitaxial growth process, electron beam deposition, physical vapor deposition (PVD), chemical vapor deposition (CVD), plasma laser deposition (PLD), dual-type thermal evaporation, sputtering, metal organic chemical vapor deposition (MOCVD), and the like may be used. Preferably, a metal-organic chemical vapor deposition (MOCVD) method may be used, but the embodiments of the present disclosure are not necessarily limited thereto. The plurality of semiconductor layers may include a first semiconductor layer, an active layer, and a second semiconductor layer.

After forming the semiconductor layer, a conductive layer and a contact electrode may be formed on the semiconductor layer.

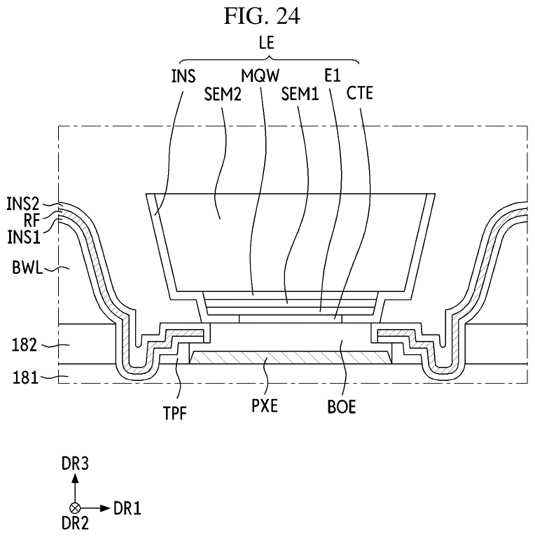

Referring to FIG. 24, the light-emitting elements LE may be transferred directly from the semiconductor substrate onto the pixel electrode PXE. Alternatively, the light-emitting elements LE may be transferred onto the pixel electrodes PXE through an electrostatic method using an electrostatic head or a stamp method using an elastic polymer material such as PDMS or silicon as a transfer substrate.

A bonding electrode BOE may be placed between the contact electrode CTE of the light-emitting element LE and the pixel electrode PXE. Then, heat is applied to the bonding electrode BOE to bond the light-emitting element LE onto the pixel electrode PXE. The bonding electrode BOE becomes fluid by receiving heat, so that the bonding electrode BOE material may be filled in the gap created between the first insulating layer INS1 and the pixel electrode PXE during the wet process.

Fifth, a common electrode CE is formed on the upper portion of the light-emitting element LE (S150 in FIG. 16).

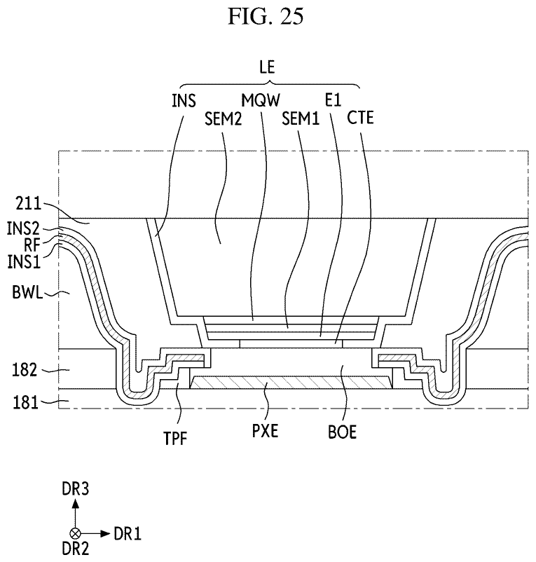

Referring to FIG. 25, a third organic layer 211 is formed to fix the light-emitting elements LE and flatten the step caused by the light-emitting elements LE. The third organic layer 211 may expose the upper portion of the light-emitting element LE.

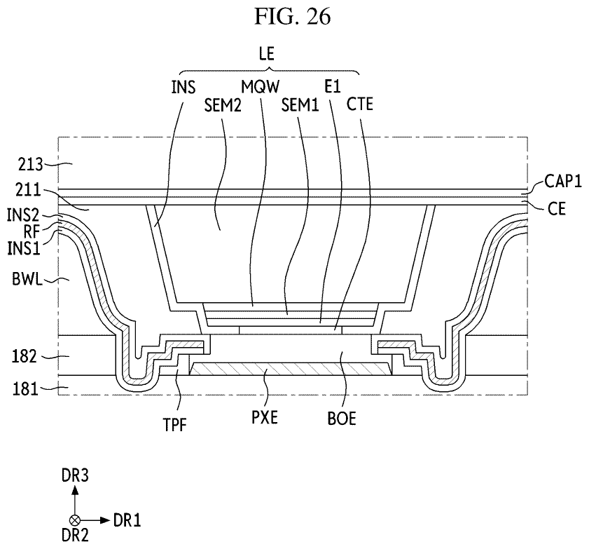

Referring to FIG. 26, a common electrode CE is formed on the light-emitting element LE and the third organic layer 211. The common electrode CE may be in direct contact with the light-emitting element LE.

Then, as shown in FIG. 7, at least one of a capping layer CAP1, a color filter CF1, CF2, and CF3 layer may be additionally formed.

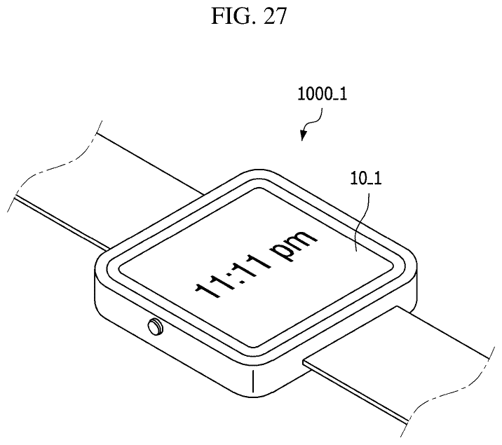

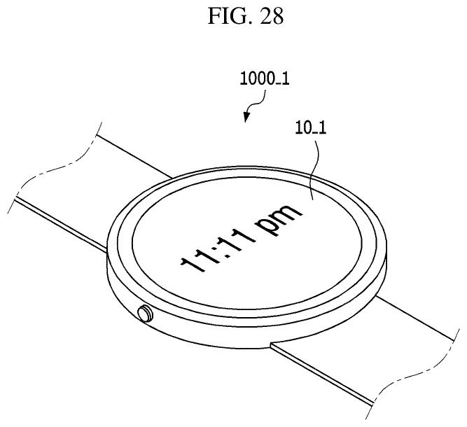

FIGS. 27 and 28 are exemplary drawings illustrating a smart watch including a display device according to an embodiment.

Referring to FIGS. 27 and 28, a display device 10_1, according to an embodiment, may be applied to a smart watch 1000_1, which is one of smart devices.

The flat shape of the display device 10_1 may be a square or a circle but is not necessarily limited thereto and may be modified in various ways, such as an oval.

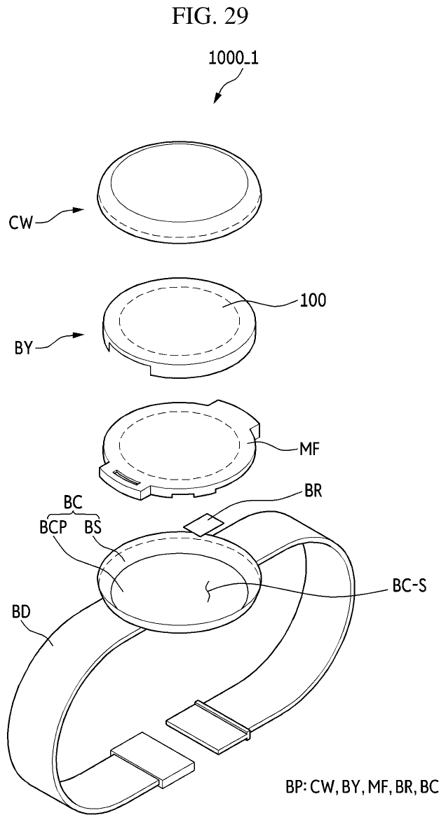

FIG. 29 is an exploded perspective view of a smart watch including a display device according to an embodiment.

Referring to FIG. 29, the smart watch 1000_1 may include a main body unit BP and a wearable portion BD.

The main body unit BP may include a display panel 100 on which an image is displayed, a cover window CW disposed on the display panel 100, a bottom cover BC disposed under the display panel 100, a middle frame MF disposed between the cover window CW and the bottom cover BC, and a battery BR disposed between the middle frame MF and the bottom cover BC. In addition to the battery BR, a main processor controlling the smart watch 1000_1, a communication chipset for wirelessly communicating with an external device, and a circuit board in which memory, etc. are mounted may be additionally disposed between the middle frame MF and the bottom cover BC.

The main body unit BP may sequentially include a bottom cover BC, a battery BR, a middle frame MF, a display panel 100, and a cover window CW.

The cover window CW is disposed on the upper portion of the display panel 10 to protect the display panel 10 and to transmit light emitted from the display panel 10. As described above, the cover window CW may include a light-blocking portion to block a portion of the light emitted from the display panel 10. The cover window CW may be made of a transparent plastic material, a glass material, or a reinforced glass material.

The cover window CW may overlap the display panel 10 and cover the front of the display panel 10. The cover window CW generally has a shape similar to that of the display panel 10 in terms of a plane, but its size may be larger than that of the display panel 10. For example, the cover window CW may protrude outward from the display panel 10. The plane shape of the cover window CW may be the same as that of the main body unit BP. For example, the planar shape of the cover window CW may be generally circular but is not necessarily limited thereto and may have various shapes, for example, a polygon such as a square or an oval.

The middle frame MF is a joining element for joining the cover window CW and the bottom cover BC and is disposed between the cover window CW and the bottom cover BC. For example, the middle frame MF may include a bracket.

The bottom cover BC is a housing disposed under the display panel 10.

The bottom cover BC may include a central cover portion BCP and a peripheral portion BS disposed around the central cover portion BCP.

The central cover portion BCP is located at the center of the bottom cover BC and may be generally flat.

The peripheral portion BS may surround the central cover portion BCP. The peripheral portion BS may be a portion that is bent and curved from the central cover portion BCP. The peripheral portion BS may be bent from the edge of the central portion CP. In some embodiments, the peripheral portion BS may include a curved surface having a predetermined curvature, and the other portion may be flat. The degree (or angle) at which the peripheral portion BS is bent from the central cover portion BCP may be an obtuse angle, but is not necessarily limited thereto, and may also be a right angle or an acute angle.

A storage space BC-S may be formed by the central cover portion BCP and the peripheral portion BS. A battery BR may be placed in the storage space BC-S.

The battery BR may be connected to a circuit board on which a main processor or the like is mounted. The display device 10_1 may be electrically connected to the circuit board to receive digital video signals, timing signals, power, and the like.

The bottom cover BC is placed on the outermost rear surface of the electronic device and may include at least one of a plastic material, a metal material, and a glass material, and may include a color coating layer. For example, the bottom cover BC, according to an example, may be a flat glass having a transparent, translucent, or opaque color coating layer.

The bottom cover BC, according to an example, may have the same shape as the cover window CW and may include a glass material having a color coating layer. For example, the bottom cover BC according to an example may have a structure symmetrical to the cover window CW with a middle frame MF in between and may include a transparent, translucent, or opaque color coating layer.

The wearing portion BD is a portion for fixing the main body unit BP to the user's wrist, for example, and may be one of a strap, a chain, and a bracelet.

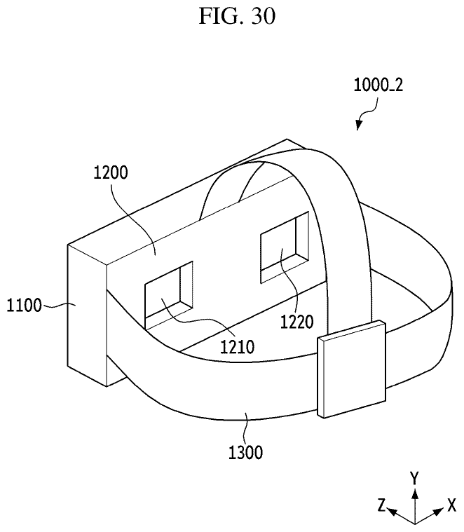

FIG. 30 is example views of a virtual reality (VR) device including a display device according to one or more embodiments.

Referring to FIG. 30, a head mounted display device 1000_2, according to one or more embodiments, include a display device housing 1100, a housing cover 1200, a first eyepiece 1210, a second eyepiece 1220, and head mounted band 1300.

The display device housing 1100 houses a display device. a head mounted display device 1000_2, according to one or more embodiments, further include a first optical element disposed between the first display device 10_2 and the first eyepiece 1210.

The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIG. 30, the present disclosure is not necessarily limited thereto. The first eyepiece 1210 and the second eyepiece 1220 may also be combined into one.

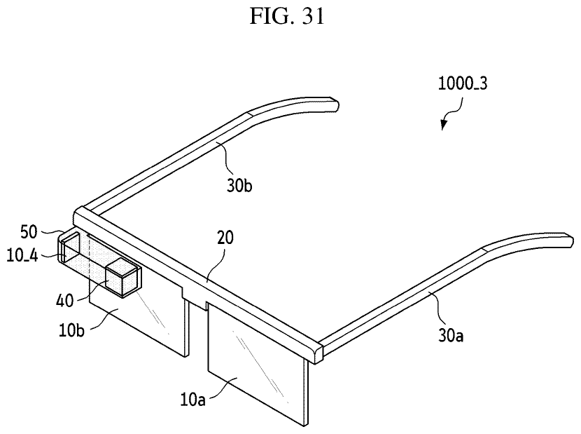

The head mounted band 1300 fixes the display device housing 1100 to a user's head so that the first eyepiece 1210 and the second eyepiece 1220 of the housing cover 1200 are kept placed on the user's left and right eyes, respectively. When the display device housing 1200 is implemented to be lightweight and small, the head mounted display device 1000_2 may include an eyeglass frame as illustrated in FIG. 31 instead of the head mounted band 1300.

The display device housing 1100 houses display device. In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 31 is an example view of a VR device including a display device according to one or more embodiments. FIG. 31 illustrates a VR device 1000_3 to which a display device 10_4 according to one or more embodiments has been applied.

Referring to FIG. 31, the VR device 1000_3, according to one or more embodiments, may be a device in the form of glasses. The VR device 1000_3 according to the embodiment may include the display device 10_4, a left lens 10a, a right lens 10b, a support frame 20, eyeglass frame legs 30a and 30b, a reflective element 40, and a display device housing 50.

In FIG. 31, a case where the VR device 1000_3 is a glasses-type display device including the eyeglass frame legs 30a and 30b is illustrated as an example. For example, the VR device 1000_3 according to the embodiment is not necessarily limited to the one illustrated in FIG. 31 and can be applied in various forms to various other electronic devices.

The display device housing 50 may include the display device 10_4 and the reflective element 40. An image displayed on the display device 10_4 may be reflected by the reflective element 40 and provided to a user's right eye through the right lens 10b. Accordingly, the user may view a VR image displayed on the display device 10_4 through the right eye.

Although the display device housing 50 is disposed at a right end of the support frame 20 in FIG. 31, the present disclosure is not necessarily limited thereto. For example, the display device housing 50 may also be disposed at a left end of the support frame 20. In this case, an image displayed on the display device 10_4 may be reflected by the reflective element 40 and provided to the user's left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

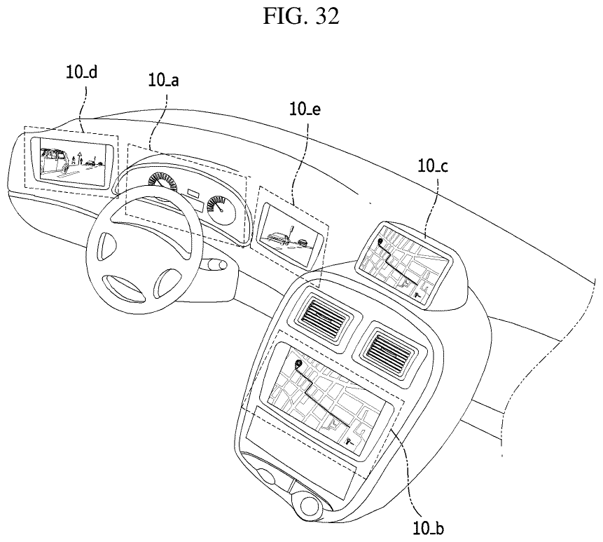

FIG. 32 is an example view illustrating a vehicle instrument cluster and center fascia including display devices according to one or more embodiments. FIG. 32 illustrates a vehicle to which display devices 10_a through 10_e according to one or more embodiments have been applied.

Referring to FIG. 32, the display devices 10_a through 10_c according to the embodiment may be applied to an instrument cluster of the vehicle, a center fascia of the vehicle, or a center information display (CID) disposed on a dashboard of the vehicle. In addition, the display devices 10_d and 10_e according to the embodiment may be applied to room mirror displays that replace side mirrors of the vehicle.

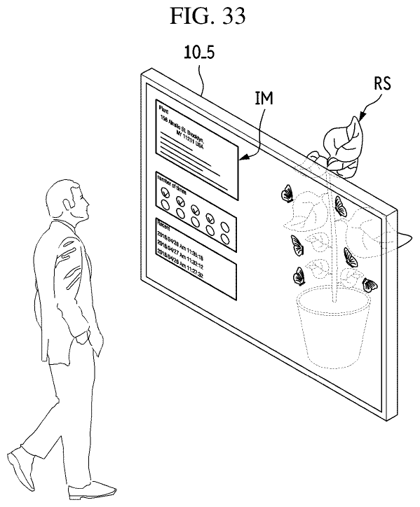

FIG. 33 is an example view of a transparent display device including a display device according to one or more embodiments.

Referring to FIG. 33, a display device 10_5, according to one or more embodiments, may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device, comprising:
a substrate;
a thin film transistor layer disposed on the substrate;
a first via layer disposed on the thin film transistor layer;
a second via layer disposed on the first via layer and having a via layer opening;
a pixel electrode layer disposed within the via layer opening, on the first via layer;
a light-emitting element disposed on the pixel electrode layer;
an organic partition wall disposed on the second via layer;
a reflective film covering the organic partition wall and including a protrusion portion extending along a side surface of the second via layer exposed by the via layer opening and a top surface of the first via layer and protruding toward the light-emitting element; and
a first insulating film disposed on a bottom surface of the reflective film,
wherein the protrusion portion overlaps an edge of the pixel electrode layer in a thickness direction, and
wherein the pixel electrode layer and the reflective film are spaced apart from each other.

2. The display device of claim 1, wherein the protrusion portion is lower than a lower end of the light-emitting element.

3. The display device of claim 1, further comprising a second insulating film disposed on a top surface of the reflective film and surrounding a top surface and side surfaces of the protrusion portion.

4. The display device of claim 1, wherein the pixel electrode layer includes a pixel electrode and a protective film surrounding side surfaces of the pixel electrode.

5. The display device of claim 4, wherein the protrusion portion overlaps the protective film in a thickness direction.

6. The display device of claim 4, wherein the protrusion portion overlaps an edge of the pixel electrode in a thickness direction and is spaced apart from the pixel electrode.

7. The display device of claim 6, wherein the first insulating film and the pixel electrode disposed on the bottom surface of the protrusion portion are spaced apart from each other.

8. The display device of claim 7, further comprising a bonding electrode disposed between the light-emitting element and the pixel electrode and extending between a bottom surface of the first insulating film and a top surface of the pixel electrode.

9. The display device of claim 1, wherein the organic partition wall comprises a single-layer organic layer or a multi-layer organic layer.

10. The display device of claim 1, wherein the organic partition wall has an inclination angle formed between a first outer surface facing the first light-emitting element and an imaginary surface extending parallel to a contact surface of the light-emitting element and a bonding electrode.

11. The display device of claim 10, wherein the inclination angle is within a range of 120 to 135 degrees, inclusive.

12. The display device of claim 4, wherein the light-emitting element further comprises a protective film disposed on side surfaces of a first semiconductor layer, an active layer, and a second semiconductor layer, and
wherein the light-emitting element does not have a reflective film disposed on any one of:
the side surfaces of the first semiconductor layer,
the active layer, and
the second semiconductor layer on the protective film.

13. The display device of claim 12, further comprising a common electrode disposed on a top surface of the light-emitting element,
wherein the light-emitting element is disposed on the pixel electrode.

14. The display device of claim 12, wherein the pixel electrode layer further comprises a common electrode,
wherein the pixel electrode and the common electrode are spaced apart from each other,
wherein the protective film surrounds a side surface of the pixel electrode and a side surface of the common electrode, and
wherein the light-emitting element is disposed on both the pixel electrode and the common electrode.

15. The display device of claim 14, wherein the light-emitting element includes a first contact electrode disposed on the pixel electrode and a second contact electrode disposed on the common electrode.

16. A method for manufacturing a display device, comprising:
forming a pixel electrode and a protective film covering the pixel electrode on a first via layer of a substrate;
covering the protective film with a via material layer on the first via layer, and forming an organic partition wall on the via material layer;
forming a second via layer having a first opening exposing the protective film by ashing a portion of the via material layer;
forming a first insulating layer and a reflective film covering the organic partition wall and exposing the protective film in the first opening;
forming an insulating material layer surrounding the reflective film, first etching the insulating material layer in the first opening to form a second insulating layer, and then second etching the protective film to expose the pixel electrode, after the first etching has been performed; and
bonding a light-emitting element to the pixel electrode,
wherein the reflective film has a protrusion portion extending along a top surface of the first via layer and protruding toward the light-emitting element and overlapping an edge of the pixel electrode in a thickness direction.

17. The method of 16, wherein the first etching is a dry etching and the second etching is a wet etching, and
wherein an etchant of the first etching is a material that etches the material layer but does not etch the protective film.

18. The method of 16, wherein a bonding electrode is disposed between the light-emitting element and the pixel electrode, and the light-emitting element is bonded to the pixel electrode by hot pressing.

19. An electronic device, comprising:
a display panel;
a window disposed on the display panel; and
a bottom cover disposed below the display panel,
wherein the display panel includes,
a substrate;
a thin film transistor layer disposed on the substrate;
a first via layer disposed on the thin film transistor layer;
a second via layer disposed on the first via layer and having a via layer opening;
a pixel electrode layer disposed within the via layer opening on the first via layer;
a light-emitting element disposed on the pixel electrode layer;
an organic partition wall disposed on the second via layer;
a reflective film covering the organic partition wall and including a protrusion portion extending along a side surface of the second via layer exposed by the via layer opening and a top surface of the first via layer and protruding toward the light-emitting element; and
a first insulating film disposed on a bottom surface of the reflective film,
wherein the protrusion portion overlaps an edge of the pixel electrode layer in a thickness direction, and
wherein the pixel electrode layer and the reflective film are spaced apart from each other.

20. The electronic device of claim 19, further comprising a battery disposed in a space of the bottom cover and supplying power to the display panel; and
a middle frame disposed between the window and the bottom cover.
